(19) United States
(12) Patent Application Publication
(10) Pub. No.: US 2026/0262291 A1
(43) Pub. Date: Sep. 3, 2026

(54) DISPLAY MODULE AND DRIVING METHOD THEREFOR, AND DISPLAY DEVICE

(71) Applicants: HEFEI BOE OPTOELECTRONICS TECHNOLOGY CO., LTD., Hefei, Anhui (CN); BOE TECHNOLOGY GROUP CO., LTD., Beijing (CN); BEIJING BOE TECHNOLOGY DEVELOPMENT CO., LTD., Beijing (CN)

(72) Inventors: Wei Xue, Beijing (CN); Hongmin Li, Beijing (CN); Bingbing Wu, Beijing (CN); Jun Hu, Beijing (CN); Biqi Li, Beijing (CN)

(73) Assignees: HEFEI BOE OPTOELECTRONICS TECHNOLOGY CO., LTD., Hefei, Anhui (CN); BOE TECHNOLOGY GROUP CO., LTD., Beijing (CN); BEIJING BOE TECHNOLOGY DEVELOPMENT CO., LTD., Beijing (CN)

(21) Appl. No.: 18/993,298

(22) PCT Filed: Apr. 17, 2024
(86) PCT No.: PCT/CN2024/088426

§ 371 Date: Jan. 10, 2025

(30) Foreign Application Priority Data
May 22, 2023 (CN) 202310595097.4

(51) Int. Cl. H10D 86/40; G06F 3/041; G06F 3/044; G09G 3/20

(52) U.S. Cl. CPC H10D 86/441; G06F 3/0412; G06F 3/04164; G06F 3/0446; G09G 3/20; H10D 86/421; H10D 86/451; G06F 2203/04107; G06F 2203/04111; G09G 2354/00; G09G 2358/00; G09G 2360/144

(57) ABSTRACT

A display module and a driving method thereof, and a display device, relate to the technical field of displaying. The display module includes: a display panel, including an effective display area, wherein the effective display area includes at least one sub-display area; and an anti-peeping panel, arranged on at least one side of the display panel in stacked, and arranged close to a light-emitting surface of the display panel and/or arranged away from the light-emitting surface, wherein the anti-peeping panel includes an anti-peeping area, the anti-peeping area includes a driving structure and functional particles, the driving structure is used for forming an electric field, and the electric field is used for driving the functional particles to move, so that a target sub-display area is in an anti-peeping state or a shared state, wherein the target sub-display area includes one or more sub-display areas.

### CROSS-REFERENCE TO RELATED APPLICATION

The present application claims the priority of the Chinese patent application filed on May 22, 2023 before the CNIPA, China National Intellectual Property administration with the application number of 202310595097.4 and the title of “DISPLAY MODULE AND DRIVING METHOD THEREFOR, AND DISPLAY DEVICE”, which is incorporated herein in its entirety by reference.

### TECHNICAL FIELD

The present application relates to the technical field of displaying and more particularly, to a display module and driving method therefor, and a display device.

### BACKGROUND

With the development of the times and the advancement of technology, display screen technology is also developing rapidly and synchronously. Traditional vehicle display screens are no longer able to meet the requirements of vehicle manufacturers or consumers.

### SUMMARY

The present application provides a display module, including:
a display panel, including an effective display area, wherein the effective display area includes at least one sub-display area; and
an anti-peeping panel, arranged on at least one side of the display panel in stacked, and arranged close to a light-emitting surface of the display panel and/or arranged away from the light-emitting surface, wherein the anti-peeping panel includes an anti-peeping area, the anti-peeping area includes a driving structure and functional particles, the driving structure is used for forming an electric field, and the electric field is used for driving the functional particles to move, so that a target sub-display area is in an anti-peeping state or a shared state, wherein the target sub-display area includes one or more sub-display areas.

In some implementations, the display panel further includes:
a border area, located on at least one side of the effective display area;
an ambient light sensing device, located in the border area, wherein the ambient light sensing device includes a first thin-film transistor and a second thin-film transistor, the first thin-film transistor includes a first active layer, and the second thin-film transistor includes a second active layer; and
a light-shielding layer, located on a side of the ambient light sensing device close to the light-emitting surface, wherein the light-shielding layer is provided with a first opening and a first light-shielding pattern, in a normal direction of the light-emitting surface, the first opening penetrates the light-shielding layer, an orthographic projection of the first opening on the light-emitting surface at least partially overlaps with an orthographic projection of the first active layer on the light-emitting surface, and an orthographic projection of the first light-shielding pattern on the light-emitting surface at least covers an orthographic projection of the second active layer on the light-emitting surface.

In some implementations, the display panel further includes:
a third thin-film transistor, located in the effective display area, wherein the third thin-film transistor includes a third active layer, a size of the orthographic projection of the first active layer on the light-emitting surface is less than a size of an orthographic projection of the third active layer on the light-emitting surface.

In some implementations, the ambient light sensing device includes a plurality of first thin-film transistors and a plurality of second thin-film transistors;
gates of the plurality of first thin-film transistors are connected to a first gate lead, drains of the plurality of first thin-film transistors are connected to a first drain lead, and sources of the plurality of first thin-film transistors are connected to a first source lead; and
gates of the plurality of second thin-film transistors are connected to a second gate lead, drains of the plurality of second thin-film transistors are connected to a second drain lead, and sources of the plurality of second thin-film transistors are connected to a second source lead.

In some implementations, the first gate lead is located on a side of the first active layer away from the light-emitting surface, and an orthographic projection of the first gate lead on the light-emitting surface at least covers orthographic projections of a plurality of first active layers on the light-emitting surface; and
the second gate lead is located on a side of the second active layer away from the light-emitting surface, and an orthographic projection of the second gate lead on the light-emitting surface at least covers orthographic projections of a plurality of second active layers on the light-emitting surface.

In some implementations, a distance between a boundary of the orthographic projection of the first gate lead on the light-emitting surface and a boundary of the orthographic projection of the first active layer on the light-emitting surface is greater than or equal to 3 micrometers; and
a distance between a boundary of the orthographic projection of the second gate lead on the light-emitting surface and a boundary of the orthographic projection of the second active layer on the light-emitting surface is greater than or equal to 3 micrometers.

In some implementations, the effective display area includes a first sub-display area, the display panel further includes a first light-transmitting area and a first bridging area located on at least one side of the first light-transmitting area, and the first sub-display area is located on at least one side of the first bridging area;
the anti-peeping panel further includes a second light-transmitting area and a second bridging area located on at least one side of the second light-transmitting area, and the anti-peeping area is located on at least one side of the second bridging area;
wherein, in the normal direction of the light-emitting surface, the first light-transmitting area at least partially overlaps with the second light-transmitting area, and the first light-transmitting area and the second light-transmitting area are capable of transmitting ambient light.

In some implementations, the effective display area includes:
a plurality of first sub-pixels, including a first domain sub-pixel and a first adjacent sub-pixel, wherein the first adjacent sub-pixel is arranged close to the first bridging area, the first domain sub-pixel is located on a side of the first adjacent sub-pixel away from the first bridging area, and an opening area of the first adjacent sub-pixel is less than or equal to an opening area of the first domain sub-pixel.

In some implementations, the display panel further includes:
a touch control circuit, wherein the touch control circuit includes a plurality of touch partitions, touch electrodes located in a same touch partition are connected to a same bonding terminal, and touch electrodes located in different touch partitions are connected to different bonding terminals;
wherein the plurality of touch partitions include a first touch partition and a second touch partition, the first touch partition is arranged close to the first bridging area, the second touch partition is located on a side of the first touch partition away from the first bridging area, and an area of the first touch partition is greater than or equal to an area of the second touch partition.

In some implementations, relative deviation between the area of the first touch partition and the area of the second touch partition is less than or equal to 10%.

In some implementations, the effective display area includes a plurality of first sub-pixels, and each of the plurality of first sub-pixels includes:
a first pixel electrode and a first common electrode, wherein orthographic projections of the first pixel electrode and the first common electrode on the light-emitting surface are arranged alternately along a first direction;
wherein a plurality of first common electrodes located in a same touch partition are connected to each other and reused as the touch electrodes, and first common electrodes located in different touch partitions are insulated from each other.

In some implementations, the display panel includes a first array substrate, a first cell substrate, and a first supporting structure located between the first array substrate and the first cell substrate, the first supporting structure includes:
a first support pillar, located in the first light-transmitting area, wherein in a state without an external pressure, a first gap is provided between the first support pillar and the first array substrate.

In some implementations, the first supporting structure further includes:
at least one second support pillar and at least one third support pillar that are located in the first bridging area, wherein the at least one second support pillar is arranged close to the first light-transmitting area, and the at least one third support pillar is arranged close to the first sub-display area, in the state without the external pressure, a second gap is provided between the second support pillar and the first array substrate, and a third gap is provided between the third support pillar and the first array substrate;
wherein the first gap is greater than or equal to the second gap, and the second gap is greater than or equal to the third gap.

In some implementations, the first supporting structure further includes:
a first supporting wall, located between the at least one second support pillar and the at least one third support pillar, and being a closed structure surrounding the first light-transmitting area; wherein
in the state without the external pressure, a fourth gap is provided between the first supporting wall and the first array substrate, the fourth gap is greater than or equal to the third gap, and less than or equal to the second gap.

In some implementations, the first supporting structure further includes:
a fourth support pillar, located in the first sub-display area, wherein a size of an orthographic projection of the fourth support pillar on the light-emitting surface is less than a size of an orthographic projection of the first support pillar on the light-emitting surface.

In some implementations, a size of an orthographic projection of the first support pillar on the light-emitting surface is greater than or equal to 1 mm, and less than or equal to 10 mm.

In some implementations, the anti-peeping panel includes a second array substrate, a second cell substrate and a second supporting structure located between the second array substrate and the second cell substrate, and the second supporting structure includes:
a fifth support pillar, located in the second light-transmitting area, wherein in a state without an external pressure, a fifth gap is provided between the fifth support pillar and the second array substrate; and
a sixth support pillar and a seventh support pillar that are located in the second bridging area, wherein the sixth support pillar is arranged close to the second light-transmitting area, and the seventh support pillar is arranged close to the anti-peeping area, in the state without the external pressure, a sixth gap is provided between the sixth support pillar and the second array substrate, and a seventh gap is provided between the seventh support pillar and the second array substrate;
wherein the fifth gap is greater than or equal to the sixth gap, and the sixth gap is greater than or equal to the seventh gap.

In some implementations, a first wiring is arranged in the first bridging area, the first wiring is used for connecting wirings in the first sub-display area separated by the first light-transmitting area, a second wiring is arranged in the second bridging area, and the second wiring is used for connecting wirings in the anti-peeping area separated by the second light-transmitting area;
the display panel further includes: a second light-shielding pattern, located in the first bridging area and arranged on a side of the first wiring close to the light-emitting surface;
the anti-peeping panel further includes: a third light-shielding pattern, located in the second bridging area and arranged on a side of the second wiring close to the light-emitting surface;
wherein an orthographic projection of the third light-shielding pattern on the light-emitting surface covers an orthographic projection of the second light-shielding pattern on the light-emitting surface, and a distance between a boundary of the orthographic projection of the third light-shielding pattern on the light-emitting surface and a boundary of the orthographic projection of the second light-shielding pattern on the light-emitting surface is greater than or equal to a preset value, the preset value is positively correlated with a thickness of an optical adhesive layer arranged between the display panel and the anti-peeping panel.

In some implementations, the display panel includes a plurality of first scanning signal lines, a plurality of first data signal lines intersecting with the first scanning signal lines, and a plurality of first sub-pixels arranged in an array along a row direction and a column direction; and
two first sub-pixels located in a same row and two adjacent columns are connected to different first scanning signal lines, and connected to a same first data signal line, a thickness of the first scanning signal lines is greater than or equal to 6000 angstroms.

In some implementations, the display panel includes: a first substrate, and a first conductive pattern and a second conductive pattern that are arranged on a side of the first substrate in stacked; the first conductive pattern is arranged close to the first substrate, the first conductive pattern and the first scanning signal lines are arranged on a same layer and have a same material and thickness, the second conductive pattern includes a plurality of second conductive wires, a distance between two adjacent second conductive wires is greater than or equal to 3.1 micrometers.

In some implementations, the effective display area includes a plurality of first sub-pixels arranged in an array along a row direction and a column direction, the anti-peeping area includes a plurality of second sub-pixels arranged in an array along the row direction and the column direction; and
in the row direction and/or the column direction, a difference between a positive integer multiple of a size of the first sub-pixel, and a size of the second sub-pixel is greater than 0 or less than 0.

In some implementations, the anti-peeping area includes a plurality of second sub-pixels arranged in an array along a row direction and a column direction, the anti-peeping panel includes a plurality of second scanning signal lines and a plurality of second signal lines intersecting with the second scanning signal lines, the plurality of second signal lines include a second common signal line and a second data signal line;
each of the plurality of second scanning signal lines includes a first extension line and a second extension line that are sequentially cross connected and alternately arranged, an angle between the first extension line and the row direction and an angle between the second extension line and the row direction are greater than or equal to 45°, and less than or equal to 75°; and
each of the plurality of second signal lines includes a third extension line and a fourth extension line that are sequentially cross connected and alternately arranged, an angle between the third extension line and the column direction and an angle between the fourth extension line and the column direction are greater than or equal to 0°, and less than or equal to 15°.

In some implementations, the plurality of second scanning signal lines are arranged along the column direction, two adjacent second scanning signal lines are parallel to each other; and
the second common signal line and the second data signal line are alternately arranged along the row direction, two adjacent second common signal lines are parallel to each other, two adjacent second data signal lines are parallel to each other, and the second common signal line and the second data signal line that are adjacent are not parallel.

In some implementations, the anti-peeping area includes a plurality of second sub-pixels arranged in an array along a row direction and a column direction, the functional particles located in the second sub-pixel include liquid crystal molecules, and the driving structure located in the second sub-pixel includes:
a second pixel electrode and a second common electrode that extend along the column direction, wherein an orthographic projection of the second pixel electrode on the light-emitting surface and an orthographic projection of the second common electrode on the light-emitting surface are arranged alternately and at equal intervals along the row direction.

In some implementations, the effective display area includes a second sub-display area, and the display module further includes:
a cover plate, arranged close to the light-emitting surface of the display panel; and
a vibration exciter, arranged on a side of the cover plate close to the display panel, symmetrically arranged on opposite sides of the second sub-display area, and arranged close to an edge of the cover plate.

The present application provides a display device, including:
the display module according to any one of the implementations; and
a driving component, connected to the display module, and used for providing a display signal and a driving signal to the display module.

The present application provides a driving method, applied to the display module according to any one of the implementations, and the driving method includes:
providing a display signal to the display panel, to display an image on the display panel;
providing a driving signal to the driving structure, wherein the driving structure responds to the driving signal to form the electric field, the electric field is used for controlling the functional particles to move, so that the target sub-display area switches to the anti-peeping state or the shared state, wherein the target sub-display area includes one or more sub-display areas.

In some implementations, the display panel includes a plurality of sub-display areas, and the step of providing the display signal to the display panel includes:
providing different display signals to different sub-display areas, to display different display images on different sub-display areas.

In some implementations, the plurality of sub-display areas include a second sub-display area and a third sub-display area that are adjacent, the anti-peeping area includes a first anti-peeping area and a second anti-peeping area, in a normal direction of the light-emitting surface, the first anti-peeping area overlaps with the second sub-display area, the second anti-peeping area overlaps with the third sub-display area, and the step of providing the driving signal to the driving structure includes:
providing a first driving signal to the driving structure in the first anti-peeping area, to make the second sub-display area in the shared state; and
providing a second driving signal to the driving structure in the second anti-peeping area, to make the third sub-display area in the anti-peeping state.

In some implementations, a first pixel, a second pixel and a third pixel are arranged at a junction of the second sub-display area and the third sub-display area, in a direction from the second sub-display area pointing to the third sub-display area, the first pixel, the second pixel and the third pixel are sequentially arranged, and the step of providing different display signals to different sub-display areas includes:
providing a first display signal to the first pixel, to make the first pixel display a first grayscale;
providing a second display signal to the second pixel, to make the second pixel display a second grayscale; and
providing a third display signal to the third pixel, to make the third pixel display a third grayscale;
wherein the second grayscale is between the first grayscale and the third grayscale.

The above description is only an overview of the technical solution of the present application. In order to have a clearer understanding of the technical means of the present application, it may be implemented according to the content of the specification. In order to make the above and other purposes, features, and advantages of the present application more obvious and understandable, the detailed description of the present application is listed below.

### BRIEF DESCRIPTION OF THE DRAWINGS

In order to more clearly illustrate the technical solutions of the embodiments of the present application or the related art, the figures that are required to describe the embodiments or the related art will be briefly described below. Apparently, the figures that are described below are some embodiments of the present application, and a person skilled in the art may obtain other figures according to these figures without creative work. It should be noted that the scale in the attached figures is only for illustration and does not represent the actual scale.

FIG. 1 exemplarily shows a schematic structural diagram of a display module;

FIG. 2 exemplarily shows a schematic structural diagram of an effective display area;

FIG. 3 exemplarily shows a schematic diagram of a planar structure of an ambient light sensing device;

FIG. 4 exemplarily shows a schematic structure of a sectional structure of an ambient light sensing device;

FIG. 5 exemplarily shows a schematic diagram of sectional structures of a first thin-film transistor and a third thin-film transistor;

FIG. 6 exemplarily shows a schematic diagram of connecting a plurality of first thin-film transistors to a first gate lead, a first drain lead, and a first source leads, and a schematic diagram of connecting a plurality of second thin-film transistors to a second gate lead, a second drain lead, and a second source lead;

FIG. 7 exemplarily shows a schematic diagram of a planar structure of a first light-transmitting area and a first bridging area;

FIG. 8 exemplarily shows a schematic diagram of a planar structure and a display effect diagram of a boundary between the first bridging area and the first display area;

FIG. 9 exemplarily shows a schematic diagram of a planar structure of a touch control circuit;

FIG. 10 exemplarily shows a schematic structural diagram of a touch control circuit and a display panel;

FIG. 11 exemplarily shows a schematic diagram of a planar structure of a touch control circuit;

FIG. 12 exemplarily shows a schematic structure of a sectional structure of a display panel;

FIG. 13 exemplarily shows PV value test results of a display panel;

FIG. 14 exemplarily shows a schematic diagram of a sectional structure of an anti-peeping panel;

FIG. 15 exemplarily shows a schematic diagram of a planar structure of a display panel;

FIG. 16 exemplarily shows a schematic diagram of a planar structure of another display panel;

FIG. 17 exemplarily shows a schematic diagram of a planar structure of an anti-peeping panel;

FIG. 18 exemplarily shows a schematic diagram of a partially enlarged planar structure of an anti-peeping panel;

FIG. 19 exemplarily shows a display effect diagram of a boundary between a second sub-display area and a third sub-display area;

FIG. 20 exemplarily shows another display effect diagram of a boundary between a second sub-display area and a third sub-display area; and

FIG. 21 exemplarily shows a schematic diagram of a position of a vibration exciter in a display module.

### DETAILED DESCRIPTION

In order to clarify the purpose, technical solution, and advantages of the embodiment of the present application, a clear and complete description of the technical solution in the embodiment of the present application will be provided below in conjunction with the accompanying drawings in the embodiment of the present application. Obviously, the described embodiments are a part of the embodiment of the present application, not the entire embodiment. Based on the embodiment of the present application, all other embodiments obtained by persons skilled in the art without creative work are within the scope of protection of the present application.

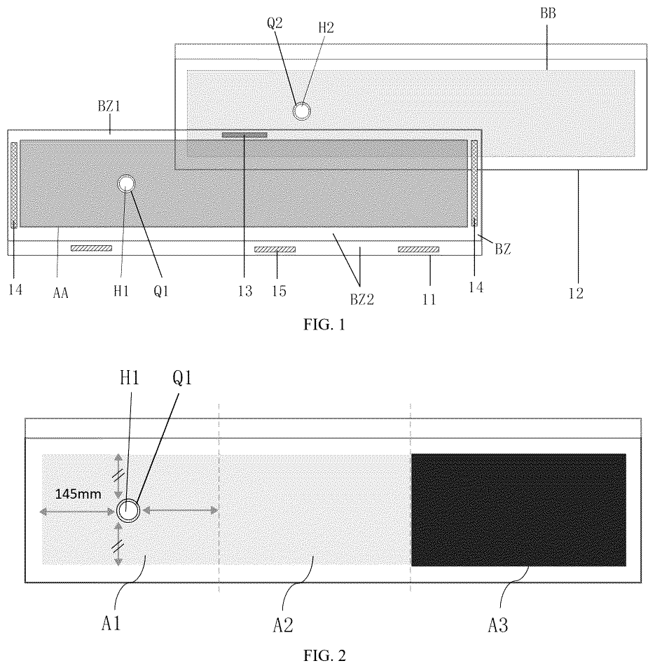

Referring to FIG. 1, it exemplarily shows a schematic structural diagram of a display module provided in the present application. The display module includes: a display panel 11, including an effective display area AA, wherein the effective display area AA includes at least one sub-display area; and an anti-peeping panel 12, arranged on at least one side of the display panel 11 in stacked, and arranged close to a light-emitting surface of the display panel 11 and/or arranged away from the light-emitting surface, wherein the anti-peeping panel 12 includes an anti-peeping area BB, the anti-peeping area BB includes a driving structure and functional particles, the driving structure is used for forming an electric field, and the electric field is used for driving the functional particles to move, so that a target sub-display area is in an anti-peeping state or a shared state, wherein the target sub-display area includes one or more sub-display areas.

The display module provided in the present application may be applied to in-vehicle displays and may also be used in consumer electronics products, and the present application does not limit this.

In one example, the display panel 11 may include one sub-display area, and this sub-display area may be used, for example, to implement the co-driver's audio-visual display function.

In another example, the display panel 11 may include a plurality of sub-display areas, such as three sub-display areas, as shown in FIG. 2, which are the first sub-display area A1, the second sub-display area A2, and the third sub-display area A3, respectively. The first sub-display area A1 may be used to implement instrument display functions, the second sub-display area A2 may be used to implement central control display functions, and the third sub-display area A3 may be used to implement audio-visual display functions. In this example, the display panel 11 integrates functions such as instrument display, central control display, and co-driver's audio-visual display. Compared with traditional in-vehicle displays that achieve different display functions through different display panels 11, the present application integrates a plurality of display functions into one display panel 11, which may simplify the structure of the display module, and reduce design difficulty and costs.

In the in-vehicle display scenario, whether the display panel 11 independently displays the co-driver's audio-visual image, or integrated displays the instrument image, the central control image, and the co-driver's audio-visual image, there are safety hazards. That is, when the co-driver engages in audio-visual entertainment, videos and sounds inevitably interfere with the attention of the driver and cause safety hazards, especially videos. In related art, in order to provide an anti-peeping function for the audio-visual displays, anti-peeping films are mostly installed in backlight modules. However, the addition of the anti-peeping films results in the audio-visual display always being in an anti-peeping state and unable to be shared, even in safe environments such as parking where the driver cannot share the audio-visual entertainment with the co-driver.

The present application sets an anti-peeping panel 12 on at least one side of the display panel 11, and provides a driving signal to the driving structure in the anti-peeping panel 12 through a driving component. The driving structure forms an electric field in response to the driving signal, and the functional particles move under the action of the electric field, thereby causing one or more sub-display areas (i.e., the target sub-display area) of the display panel 11 to be in an anti-peeping state or a shared state. By providing different driving signals, it is possible to switch between the anti-peeping state and the shared state. Among them, the target sub-display area may be a partial sub-display area of the display panel 11, or all sub-display areas, that is, the anti-peeping panel 12 may locally adjust the anti-peeping/shared state of the display panel 11.

In this way, during the driving process of the driver, the display area for displaying the audio-visual image may be switched to the anti-peeping state to avoid the audio-visual image distracting the attention of the driver, thereby improving the driving safety factor. In a safe environment such as parking, the display area of the audio-visual image may be switched to the shared state, thus allowing the driver and co-driver to share the audio-visual entertainment and improve the user experience.

In some implementations, as shown in FIG. 1, the display panel 11 further includes: a border area BZ, located on at least one side of the effective display area AA; an ambient light sensing device 13, located in the border area BZ, wherein as shown in FIG. 3, the ambient light sensing device 13 includes a first thin-film transistor T1 and a second thin-film transistor T2, the first thin-film transistor T1 includes a first active layer ACT1, and the second thin-film transistor T2 includes a second active layer ACT2; and a light-shielding layer 31, located on a side of the ambient light sensing device 13 close to the light-emitting surface, wherein the light-shielding layer 31 is provided with a first opening 311 and a first light-shielding pattern 312, in a normal direction of the light-emitting surface (that is, a stacking direction of the display panel 11 and the anti-peeping panel 12), the first opening 311 penetrates the light-shielding layer 31, an orthographic projection of the first opening 311 on the light-emitting surface at least partially overlaps with an orthographic projection of the first active layer ACT1 on the light-emitting surface, and an orthographic projection of the first light-shielding pattern 312 on the light-emitting surface at least covers an orthographic projection of the second active layer ACT2 on the light-emitting surface.

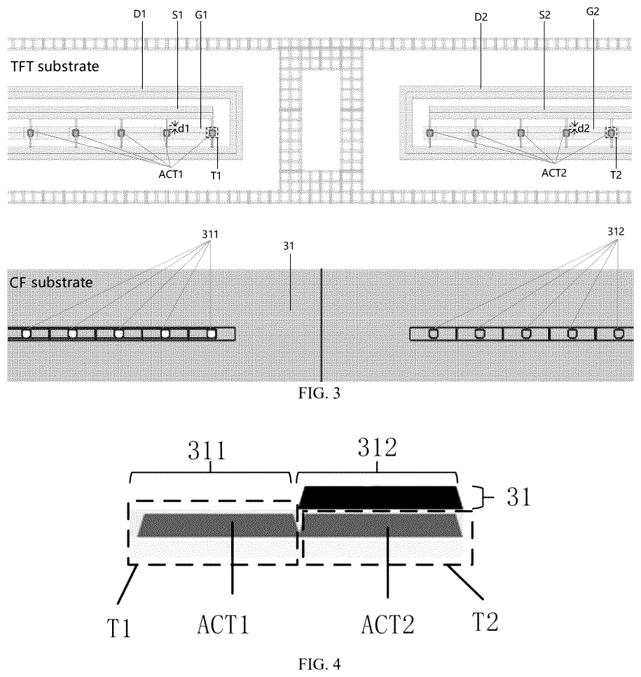

As shown in FIG. 4, the second active layer ACT2 of the second thin-film transistor T2 is blocked by the first light-shielding pattern 312 from the ambient light, while the first active layer ACT1 of the first thin-film transistor T1 is unobstructed on the side close to the light-emitting surface and may receive the ambient light. In this way, when the ambient light is irradiated onto the first active layer ACT1, the channel current of the first thin-film transistor T1 changes, while the channel current of the second thin-film transistor T2 does not change. Different ambient light intensities cause different changes in the channel current of the first thin-film transistor T1. Therefore, the intensity of the ambient light may be determined based on the difference in channel current between the first thin-film transistor T1 and the second thin-film transistor T2.

This implementation increases the ambient light sensing function of the display panel 11 by setting the ambient light sensing device 13 in the border area BZ of the display panel 11, without the need to separately configure an ambient light sensor in the display module, simplifying the module structure and reducing costs.

In specific implementation, the orthographic projection of the first active layer ACT1 on the light-emitting surface may completely overlap with the orthographic projection of the first opening 311 on the light-emitting surface, or the orthographic projection of the first active layer ACT1 on the light-emitting surface may be located within a range of the orthographic projection of the first opening 311 on the light-emitting surface, which may increase the receiving area of the first active layer ACT1 for the ambient light.

In specific implementation, the orthographic projection of the first light-shielding pattern 312 on the light-emitting surface may completely overlap with the orthographic projection of the second active layer ACT2 on the light-emitting surface, or in order to fully block the second active layer ACT2 and prevent the ambient light from entering the second active layer ACT2 from the side, the orthographic projection area of the first light-shielding pattern 312 on the light-emitting surface may be greater than that of the second active layer ACT2 on the light-emitting surface.

For example, as shown in FIG. 3, in addition to the first opening 311, the light-shielding layer 31 located in the border area BZ may be a continuous integrated structure, which is also used to block the pattern of the ambient light sensing device 13 and connect the leads of the ambient light sensing device 13.

In FIG. 1, the border area BZ is arranged around the effective display area AA.

For example, the border area BZ includes a sub-border area located on one side of the effective display area AA (such as the left border, right border, upper border, or lower border in FIG. 1), and this sub-border area may be provided with one or more ambient light sensing devices 13.

For example, the border area BZ includes a plurality of sub-border areas BZ located on different sides of the effective display area AA (such as the left border, right border, upper border, and lower border in FIG. 1), and the ambient light sensing device 13 may be arranged in any one or more sub-border areas BZ.

For example, in FIG. 1, the ambient light sensing device 13 is located in the first sub-border area BZ1 (such as the upper border shown in FIG. 1), and the first sub-border area BZ1 is opposite to the second sub-border area BZ2 (such as the lower border shown in FIG. 1). The second sub-border area BZ2 includes a bonding area, the bonding area is provided with bonding terminals for bonding the driving chip.

Furthermore, as shown in FIG. 1, the ambient light sensing device 13 is centrally located in the first sub-border area BZ1 to avoid the influence of the sealing adhesive and cover plate.

For example, the first thin-film transistor T1 has a first channel, and the second thin-film transistor T2 has a second channel. In order to improve the performance consistency between different thin-film transistors, the shapes of the orthographic projections of the first channel and the second channel on the light-emitting surface are both U-shaped, but they may also be both I-shaped, etc., the present application does not limit this.

In some implementations, as shown in FIG. 5, the display panel 11 further includes: a third thin-film transistor T3, located in the effective display area AA, wherein the third thin-film transistor T3 includes a third active layer ACT3, a size of the orthographic projection of the first active layer ACT1 on the light-emitting surface is less than a size of an orthographic projection of the third active layer ACT3 on the light-emitting surface.

Since there is no obstruction on one side of the first active layer ACT1 close to the light-emitting surface, the third thin-film transistor T3 may be visible on the light-emitting side. By setting a smaller size of the first active layer ACT1, the visibility of the third thin-film transistor T3 may be reduced.

In specific implementation, the first thin-film transistor T1 and the second thin-film transistor T2 may be formed in the same process as the third thin-film transistor T3, and the present application does not limit this.

In order to improve the accuracy of ambient light detection, for example, as shown in FIG. 3, the structures, sizes, and setting numbers of the first thin-film transistor T1 and the second thin-film transistor T2 are all the same, and the present application does not limit this.

In some implementations, as shown in FIG. 3, the ambient light sensing device 13 includes a plurality of first thin-film transistors T1, gates of the plurality of first thin-film transistors T1 are all connected to a first gate lead G1, drains of the plurality of first thin-film transistors T1 are all connected to a first drain lead D1, and sources of the plurality of first thin-film transistors T1 are connected to a first source lead S1.

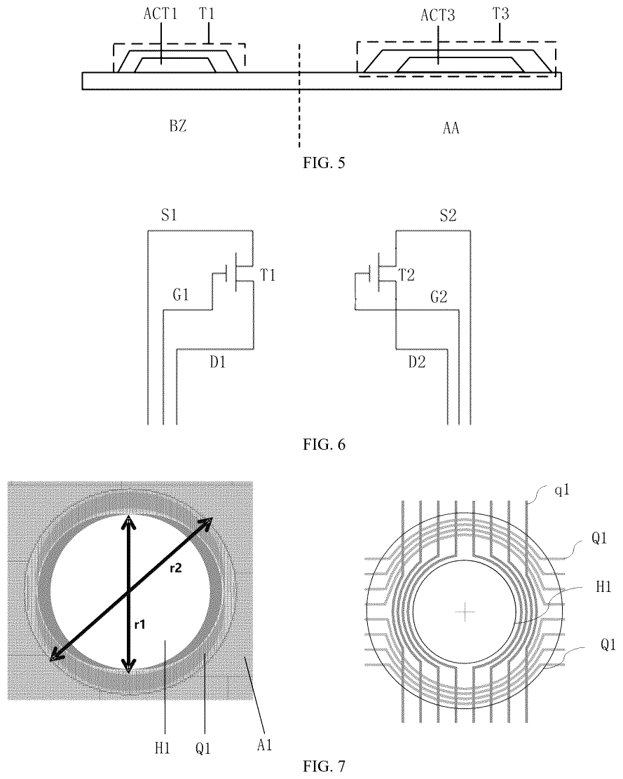

Referring to the left figure in FIG. 6, a schematic diagram of connecting the plurality of first thin-film transistors T1 to the first gate lead G1, the first drain lead D1, and the first source lead S1 is shown. By connecting the plurality of first thin-film transistors T1 in parallel, the amount of current change caused by illumination may be increased, thereby improving the sensitivity of environmental light detection.

In some implementations, as shown in FIG. 3, the ambient light sensing device 13 includes a plurality of second thin-film transistors T2, gates of the plurality of second thin-film transistors T2 are all connected to a second gate lead G2, drains of the plurality of second thin-film transistors T2 are all connected to a second drain lead D2, and sources of the plurality of second thin-film transistors T2 are connected to a second source lead S2. Referring to the right figure in FIG. 6, a schematic diagram of connecting the plurality of second thin-film transistors T2 to the second gate lead G2, the second drain lead D2, and the second source lead S2 is shown.

In this implementation, in order to avoid signal interference, as shown in FIG. 3, in the normal direction of the light-emitting surface, the first gate lead G1 and the second gate lead G2 do not overlap and are connected to different bonding terminals, the first drain lead D1 and the second drain lead D2 do not overlap and are connected to different bonding terminals, and the first source lead S1 and the second source lead S2 do not overlap and are connected to different bonding terminals.

In some implementations, as shown in FIG. 3, the first gate lead G1 is located on a side of the first active layer ACT1 away from the light-emitting surface, and an orthographic projection of the first gate lead G1 on the light-emitting surface at least covers orthographic projections of a plurality of first active layers ACT1 on the light-emitting surface. In this way, the first active layer ACT1 may be avoided from being affected by the emitted light from the backlight source at a back surface and other light sources.

In some implementations, as shown in FIG. 3, the second gate lead G2 is located on a side of the second active layer ACT2 away from the light-emitting surface, and an orthographic projection of the second gate lead G2 on the light-emitting surface at least covers orthographic projections of a plurality of second active layers ACT2 on the light-emitting surface. In this way, the second active layer ACT2 may be avoided from being affected by the emitted light from the backlight source at the back surface and other light sources.

In some implementations, as shown in FIG. 3, a distance d1 between a boundary of the orthographic projection of the first gate lead G1 on the light-emitting surface and a boundary of the orthographic projection of the first active layer ACT1 on the light-emitting surface is greater than or equal to 3 micrometers. In FIG. 3, the distance d1 between the boundary of the orthographic projection of the first gate lead G1 on the light-emitting surface and the boundary of the orthographic projection of the first active layer ACT1 on the light-emitting surface is 11.5 micrometers.

In some implementations, as shown in FIG. 3, a distance d2 between a boundary of the orthographic projection of the second gate lead G2 on the light-emitting surface and a boundary of the orthographic projection of the second active layer ACT2 on the light-emitting surface is greater than or equal to 3 micrometers. In FIG. 3, the distance d2 between the boundary of the orthographic projection of the second gate lead G2 on the light-emitting surface and the boundary of the orthographic projection of the second active layer ACT2 on the light-emitting surface is 11.5 micrometers.

For example, the channel width-to-length ratio of the first channel and the second channel are both 20 μm/4 μm, and the present application does not limit this.

For example, as shown in FIG. 3, the ambient light sensing device 13 may include 100 first thin-film transistors T1 and 100 second thin-film transistors T2. The number of the first thin-film transistors T1 and the second thin film transistors T2 in the ambient light sensing device 13 may be set according to actual needs, and the present application does not limit this.

In some implementations, as shown in FIG. 1 and FIG. 2, the effective display area AA includes a first sub-display area A1, the display panel 11 further includes a first light-transmitting area H1 and a first bridging area Q1 located on at least one side of the first light-transmitting area H1, and the first sub-display area A1 is located on at least one side of the first bridging area Q1. The anti-peeping panel 12 further includes a second light-transmitting area H2 and a second bridging area Q2 located on at least one side of the second light-transmitting area H2, and the anti-peeping area BB is located on at least one side of the second bridging area Q2. Among them, in the normal direction of the light-emitting surface, the first light-transmitting area H1 at least partially overlaps with the second light-transmitting area H2, and the first light-transmitting area H1 and the second light-transmitting area H2 are capable of transmitting the ambient light.

For example, as shown in FIG. 1, the first bridging area Q1 is arranged around the first light-transmitting area H1, and the first sub-display area A1 is arranged around the first bridging area Q1. Correspondingly, the second bridging area Q2 is arranged around the second light-transmitting area H2, and the anti-peeping area BB is arranged around the second bridging area Q2.

In specific implementation, since the first light-transmitting area H1 and the second light-transmitting area H2 may transmit the ambient light, cameras may be installed on the side of the first light-transmitting area H1 and the second light-transmitting area H2 away from the light-emitting surface. This may add the camera function of the display module, which is conducive to achieving intelligent driving and meeting the needs of human-machine interconnection in in-vehicle display applications.

In some implementations, in the normal direction of the light-emitting surface, the first light-transmitting area H1 and the second light-transmitting area H2 may completely overlap and the present application does not limit this.

In some implementations, the first sub-display area A1 may be used to display the instruments. Since the instrument panel is generally displayed directly facing the driver, in order to facilitate capturing the driving state of the driver, the first light-transmitting area H1 may be arranged in the first sub-display area A1.

Furthermore, as shown in FIG. 2, the first light-transmitting area H1 may be arranged close to the geometric center of the first sub-display area A1, for example, the first sub-display area A1 may be a sub-display area in the display panel 11 close to one side edge (such as the left edge in FIG. 2).

For example, for a 42.2-inch display panel 11, as shown in the figure, the first sub-display area A1 is close to the left edge of the display panel 11, and a distance between the first light-transmitting area H1 and the left edge of the first sub-display area A1 is 145 mm.

In some implementations, the shape of the orthographic projection of the first light-transmitting area H1 on the light-emitting surface may be a regular or irregular shape such as a circle (as shown in FIG. 1), a polygon, etc.

For example, the size of the orthographic projection of the first light-transmitting area H1 on the light-emitting surface (such as the diameter r1 of the circular H1 shown in the left figure of FIG. 7) may be greater than or equal to 1 mm and less than or equal to 10 mm, such as 1 mm, 2 mm, 3 mm, 4 mm, 5 mm, 6 mm, 7 mm, 8 mm, or 9 mm. In this way, the first light-transmitting area H1 may be compatible with most sizes of cameras.

For example, as shown in the left figure of FIG. 7, the shape of the orthographic projection of the first bridging area Q1 on the light-emitting surface is a circle. The difference between the outer diameter (the diameter r2 shown in the left figure of FIG. 7) and the inner diameter (the diameter r1 of the circle H1 shown in the left figure of FIG. 7) of the circular ring may be greater than or equal to 1 mm and less than or equal to 3 mm, such as 2 mm or 2.7 mm.

In some implementations, as shown in the right figure of FIG. 7, a first wiring is arranged in the first bridging area Q1, the first wiring is used for connecting wirings in the first sub-display area A1 separated by the first light-transmitting area H1, a second wiring is arranged in the second bridging area Q2 (not shown in FIG. 7), and the second wiring is used for connecting wirings in the anti-peeping area BB separated by the second light-transmitting area H2.

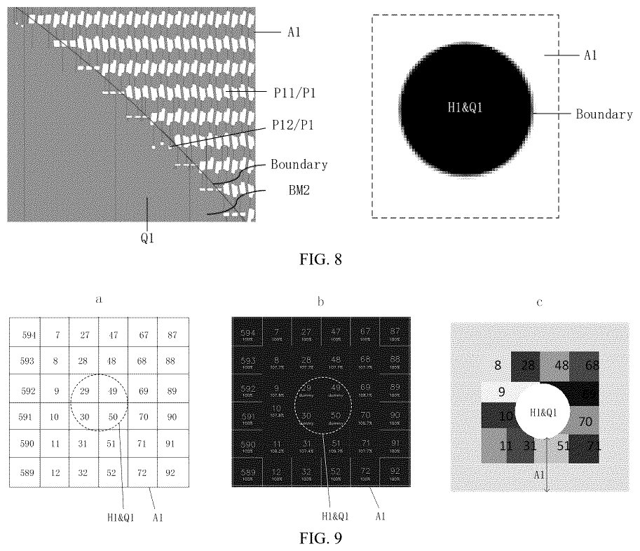

In some implementations, as shown in the left figure of FIG. 8, the effective display area AA includes a plurality of first sub-pixels P1. The plurality of first sub-pixels P1 include a first domain sub-pixel P11 and a first adjacent sub-pixel P12, the first adjacent sub-pixel P12 is arranged close to the first bridging area Q1, the first domain sub-pixel P11 is located on a side of the first adjacent sub-pixel P12 away from the first bridging area Q1, and an opening area of the first adjacent sub-pixel P12 is different from an opening area of the first domain sub-pixel P11.

Among them, the opening area refers to the area of the region that may emit light or the area of the region that may transmit the backlight.

Furthermore, the opening area of the first adjacent sub-pixel P12 is less than or equal to the opening area of the first domain sub-pixel P11. By setting the first adjacent sub-pixel P12 with a smaller opening area, such as the display effect shown in the right figure of FIG. 8, it may effectively avoid jagged edges at the boundary between the first bridging area Q1 and the first sub-display area A1, thus improving the display effect.

In some implementations, the display panel 11 further includes: a touch control circuit, wherein the touch control circuit includes a plurality of touch partitions, touch electrodes located in a same touch partition are connected to a same bonding terminal, and touch electrodes located in different touch partitions are connected to different bonding terminals. Among them, the bonding terminals are located in the bonding areas.

Referring to plan a in FIG. 9, a schematic diagram of the planar structure of the touch control circuit without the first light-transmitting area H1 and the first bridging area Q1 is shown, and the touch control circuit includes the plurality of touch partitions with approximately the same area.

In this implementation, in order to improve the transmittance of the first light-transmitting area H1 and avoid occupying the wiring space of the first bridging area Q1, no touch electrode is provided in the blind hole area formed by the first light-transmitting area H1 and the first bridging area Q1.

For example, as shown in plan a in FIG. 9, each of the four touch partitions (i.e., the partitions marked as 29, 30, 49, 50 in the figure) partially overlaps with the blind hole area (including the first light-transmitting area H1 and the first bridging area Q1), and these touch partitions may be defined as cross hole touch partitions. The touch electrodes of the cross hole touch partitions are located outside the blind hole area.

In order to make the touch electrodes of the cross hole touch partitions effective, in some implementations, the touch electrodes of different cross hole touch implementation may be connected to different bonding terminals, so as to perform touch signal input or output on the touch electrodes of the cross hole touch partitions.

In order to make the touch electrodes of the cross hole touch partitions effective, the touch electrodes of the cross hole touch partitions may also be incorporated into adjacent touch partitions. For example, in some implementations, as shown in plan b in FIG. 9, the plurality of touch partitions include a first touch partition (any one of the partitions marked as 8, 9, 10, 11, 28, 31, 48, 51, 68, 69, 70, 71 shown in plan b or c in FIG. 9) and a second touch partition (any one of the partitions marked as 589 to 594, 7, 27, 47, 67, 87 to 92, 12, 32, 52, 72 shown in plan b in FIG. 9), the first touch partition is arranged close to the first bridging area Q1, the second touch partition is located on a side of the first touch partition away from the first bridging area Q1, and an area of the first touch partition is greater than or equal to an area of the second touch partition.

In this implementation, as shown in plan b or c in FIG. 9, the touch partitions adjacent to the cross hole touch partitions (i.e., the partitions marked as 8, 9, 10, 11, 28, 31, 48, 51, 68, 69, 70, 71 in the figure) are incorporated with the touch electrodes of the four cross hole touch partitions (i.e., the partitions marked as 29, 30, 49, 50 in the figure), thus forming the first touch partition with a larger area.

In this way, by adjusting the area of the adjacent touch partitions and incorporating touch electrodes of the cross hole touch partitions, the number of the bonding terminals in the bonding area may be reduced, and wirings may be minimized.

As shown in plan b or c in FIG. 9, the plurality of first touch partitions are arranged around the periphery of the first bridging area Q1, and the plurality of second touch partitions are arranged around the periphery of the plurality of first touch partitions.

In some implementations, as shown in plan b in FIG. 9, relative deviation between the area of the first touch partition and the area of the second touch partition is less than or equal to 10%. In this way, by limiting the relative deviation between the area of the first touch partition and the area of the second touch partition to a smaller range, the touch and display effects may be improved.

For example, as shown in plan b in FIG. 9, the area of the second touch partition is 100%, the areas of the first touch partitions 8, 28, 48, 68, and 71 are 107.7%, the areas of the first touch partitions 9 and 10 are 107.8%, the area of the first touch partition 69 is 108.1%, the area of the first touch partition 70 is 108.7%, the area of the first touch partition 11 is 108.2%, the area of the first touch partition 31 is 107.4%, and the area of the first touch partition 51 is 109.7%. In plan b in FIG. 9, the relative deviation between the area of the first touch partition and the area of the second touch partition is less than or equal to 5% or 3%, which may further improve the touch and display effects.

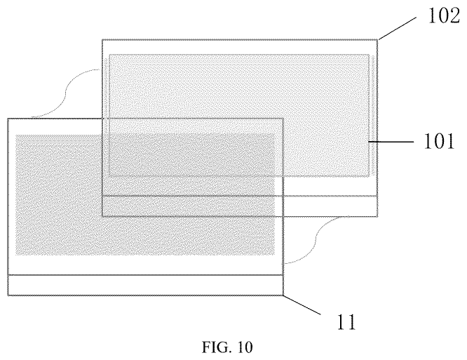

For example, as shown in FIG. 10, the touch control circuit 101 may be set independently of the display panel 11, such as on the light-emitting side of the display panel 11. In this case, the anti-peeping panel 12 may be located between the touch control circuit 101 and the display panel 11, or on the side of the display panel 11 away from the touch control circuit 101, the present application does not limit this. Among them, the display panel 11 is used to display images, and the touch control circuit 101 is used to implement touch control functions.

In this example, as shown in FIG. 10, the touch control circuit 101 may be arranged in the external touch screen 102. The structure of adding the external touch screen 102 to the display panel 11 may increase the thickness of the display module, increase assembly complexity and control module complexity, and increase costs.

For example, the touch control circuit 101 may be integrated inside the display panel 11. In this case, to avoid the anti-peeping panel 12 shielding the touch control function, the anti-peeping panel 12 may be located on the side of the display panel 11 away from the light-emitting surface.

In this example, by integrating the touch control circuits inside the display panel 11, the structure of adding the external touch screen 102 to the display panel 11 may be replaced, thereby reducing the thickness of the display module, lowering assembly complexity and control module complexity, and lowering costs.

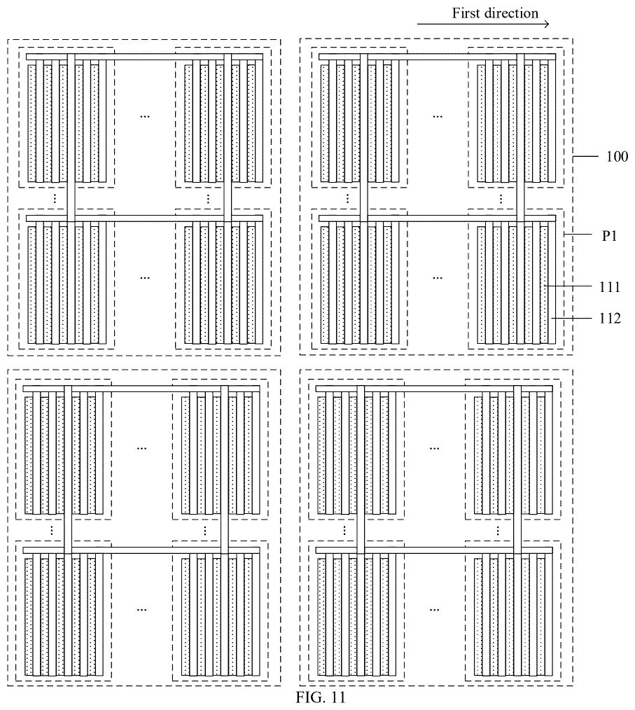

In some implementations, as shown in FIG. 11, the effective display area AA includes a plurality of first sub-pixels P1, and each of the plurality of first sub-pixels P1 includes: a first pixel electrode 111 and a first common electrode 112, wherein orthographic projections of the first pixel electrode 111 and the first common electrode 112 on the light-emitting surface are arranged alternately along a first direction. Among them, a plurality of first common electrodes 112 located in a same touch partition 100 are connected to each other and reused as the touch electrodes, and first common electrodes 112 located in different touch partitions 100 are insulated from each other.

For example, during the display phase, a common voltage signal may be provided to the first common electrode 112, and a display signal may be provided to the first pixel electrode 111, thereby forming a horizontal electric field between the first pixel electrode 111 and the first common electrode 112, the horizontal electric field may drive the liquid crystal molecules to deflect. In the touch phase, touch signals may be provided to the first common electrode 112 to achieve self-capacitive touch. By time-division multiplexing the first common electrode 112, the structure of the display panel 11 may be simplified and the process flow may be simplified.

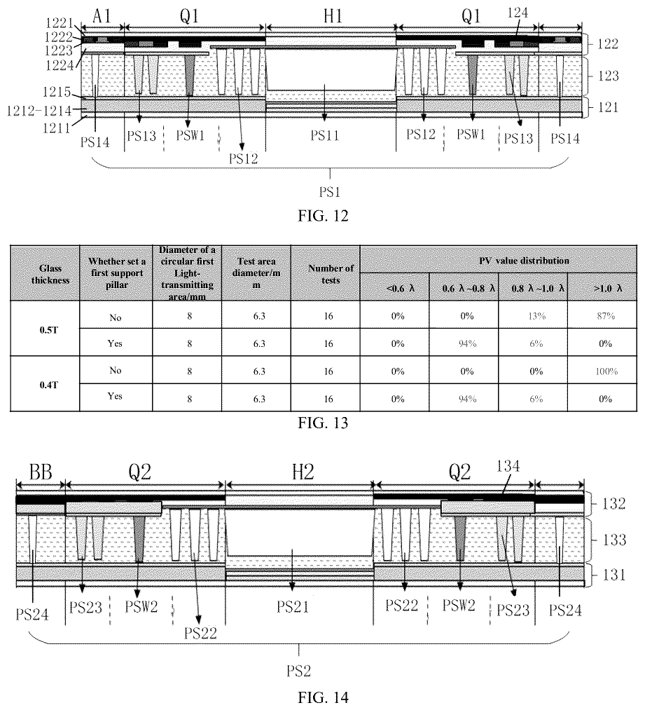

As shown in FIG. 12, the display panel 11 includes a first array substrate 121 and a first cell substrate 122 arranged oppositely, and may also include a first liquid crystal layer 123 filled between the first array substrate 121 and the first cell substrate 122.

Due to the large size of the cameras used in the field of in-vehicle displays, the corresponding size of the first light-transmitting area H1 is also large. In some embodiments, there is no support pillar between the first array substrate 121 and the first cell substrate 122 located in the first light-transmitting area H1. Therefore, the first array substrate 121 and the first cell substrate 122 in the first light-transmitting area H1 are prone to deformation, and the larger the size of the first light-transmitting area H1, the greater the deformation of the first array substrate 121 and the first cell substrate 122.

To solve the aforementioned problems, in some implementations, as shown in FIG. 12, the display panel 11 further includes: a first supporting structure PS1 located between the first array substrate 121 and the first cell substrate 122, the first supporting structure PS1 includes: a first support pillar PS11, located in the first light-transmitting area H1, wherein in a state without an external pressure, a first gap is provided between the first support pillar PS11 and the first array substrate 121.

By setting the first support pillar PS11 in the first light-transmitting area H1, the first array substrate 121 and the first cell substrate 122 of the first light-transmitting area H1 may be supported, ensuring that the box thickness of the first light-transmitting area H1 does not change too much and improving the uniformity of the box thickness.

In some implementations, as shown in FIG. 12, the first supporting structure PS1 further includes: at least one second support pillar PS12 and at least one third support pillar PS13 that are located in the first bridging area Q1, wherein the at least one second support pillar PS12 is arranged close to the first light-transmitting area H1, and the at least one third support pillar PS13 is arranged close to the first sub-display area A1, in the state without the external pressure, a second gap is provided between the second support pillar PS12 and the first array substrate 121, and a third gap is provided between the third support pillar PS13 and the first array substrate 121. Among them, the first gap is greater than or equal to the second gap, and the second gap is greater than or equal to the third gap.

For example, the first gap is 2.2 μm, the second gap is 1.0 μm, and the third gap is 0.25 μm, the present application does not limit this.

By setting the first gap, the second gap, and the third gap to gradually decrease, it may avoid frictional stress concentration caused by excessively high support pillars in the first light-transmitting area H1 and the first bridging area Q1, and avoid problems such as uneven display images and damaged image quality captured by the camera due to the frictional stress concentration.

In specific implementation, as shown in FIG. 12, the first supporting structure PS1 may include one or more (such as three in FIG. 12) second support pillars PS12 in the direction from the first light-transmitting area H1 pointing to the first bridging area Q1, and the plurality of second support pillars PS12 may be separated from each other.

In specific implementation, as shown in FIG. 12, the first supporting structure PS1 may include one or more (such as the two in FIG. 12) third support pillars PS13 in the direction from the first light-transmitting area H1 pointing to the first bridging area Q1, and the plurality of third support pillars PS13 may be separated from each other.

In some implementations, as shown in FIG. 12, the first supporting structure PS1 further includes: a first supporting wall PS21, located between the at least one second support pillar PS12 and the at least one third support pillar PS13, and being a closed structure surrounding the first light-transmitting area H1. Furthermore, in the state without the external pressure, a fourth gap is provided between the first supporting wall PS21 and the first array substrate 121, the fourth gap is greater than or equal to the third gap, and less than or equal to the second gap.

For example, as shown in FIG. 12, in the direction from the first light-transmitting area H1 pointing to the first bridging area Q1, the first supporting wall PS21 is located between the plurality of (such as three shown in FIG. 12) second support pillars PS12 and the plurality of (such as two shown in FIG. 12) third support pillars PS13, and the first supporting wall PS21 is separated from the second support pillars PS12 and the third support pillars PS13.

In some implementations, as shown in FIG. 12, the first supporting structure PS1 further includes: a fourth support pillar PS14, located in the first sub-display area A1, wherein a size of an orthographic projection of the fourth support pillar PS14 on the light-emitting surface is less than a size of an orthographic projection of the first support pillar PS11 on the light-emitting surface.

In some implementations, the size of the orthographic projection of the first support pillar PS11 on the light-emitting surface is greater than or equal to 1 mm, and less than or equal to 10 mm.

For example, the size of the orthographic projection of the fourth support pillar PS14 on the light-emitting surface is 9 μm, and the size of the orthographic projection of the first support pillar PS11 on the light-emitting surface may be 1 mm, 2 mm, 3 mm, 4 mm, 5 mm, 6 mm, 7 mm, 8 mm or 9 mm, and so on.

For example, the gap between the fourth support pillar PS14 and the first array substrate 121 may be a positive value or a negative value, the negative value indicates that the fourth support pillar PS14 is in a compressed state between the first array substrate 121 and the first cell substrate 122 in the state without the external pressure.

For example, as shown in FIG. 12, the first array substrate 121 of the first sub-display area A1 may include: a first substrate 1211, a display area first metal pattern (including a gate of a thin-film transistor) located on the first metal layer 1212, a display area insulation pattern located on the insulation layer 1213, a display area second metal pattern (including a source and drain of a thin-film transistor) located on the second metal layer 1214, and a display area passivation pattern located on the passivation layer 1215 that are arranged in stacked. Among them, the first substrate 1211 may be, for example, a glass substrate or the like.

The first cell substrate 122 in the first sub-display area A1 may include: a second substrate 1221, a display area light-shielding pattern located on the black matrix layer 1222, a display area color film pattern located on the color film layer 1223, and a display area flat pattern located on the flat layer 1224 that are arranged in stacked. Among them, the fourth support pillar PS14 is located on the side of the display area flat pattern away from the second substrate 1221. Among them, the second substrate 1221 may be, for example, the glass substrate or the like.

For example, the first array substrate 121 of the first light-transmitting area H1 includes the first substrate 1211, a light-transmitting area insulation pattern located on the insulation layer 1213, and a light-transmitting area passivation pattern located on the passivation layer 1215 that are arranged in stacked. The first array substrate 121 of the first bridging area Q1 includes: the first substrate 1211, a bridging area first metal pattern located on the first metal layer 1212, a bridging area insulation pattern located on the insulation layer 1213, a bridging area second metal pattern located on the second metal layer 1214, and a bridging area passivation pattern located on the passivation layer 1215 that are arranged in stacked.

For example, the first cell substrate 122 in the first light-transmitting area H1 includes: the second substrate 1221, and a light-transmitting area flat pattern located on the flat layer 1224 that are arranged in stacked. The first support pillar PS11 is located on the side of the light-transmitting area flat pattern away from the second substrate 1221.

For example, the first cell substrate 122 in the first bridging area Q1 close to the first light-transmitting area H1 includes: the second substrate 1221, a first bridging area light-shielding pattern located on the black matrix layer 1222, and a first bridging area flat pattern located on the flat layer 1224 that are arranged in stacked. The second support pillar PS12 is located on the side of the first bridging area flat pattern away from the second substrate 1221.

For example, the first cell substrate 122 in the first bridging area Q1 close to the first sub-display area A1 includes: the second substrate 1221, a second bridging area light-shielding pattern located on the black matrix layer 1222, a bridging area color film pattern located on the color film layer 1223, and a second bridging area flat pattern located on the flat layer 1224 that are arranged in stacked. The first supporting wall PS21 and the third support pillar PS13 are located on the side of the second bridging area flat pattern away from the second substrate 1221.

By setting the first support pillar PS11 in the first light-transmitting area H1, the PV value of the glass substrate in the first light-transmitting area H1 may be significantly improved. Among them, the PV value is used to reflect the deformation of glass. Using a fixed wavelength λ to enter the glass and reflect it back, interference fringes are formed. The more irregular the fringes are, the larger the PV value. Generally, the PV value less than 1.0 λ is required to indicate that the deformation of the glass is small. As shown in FIG. 13, regardless of whether 0.4 T glass or 0.5 T glass is used for the first substrate 1211 and the second substrate 1221, the PV value of the glass substrate in the first light-transmitting area H1 is within 1.02.

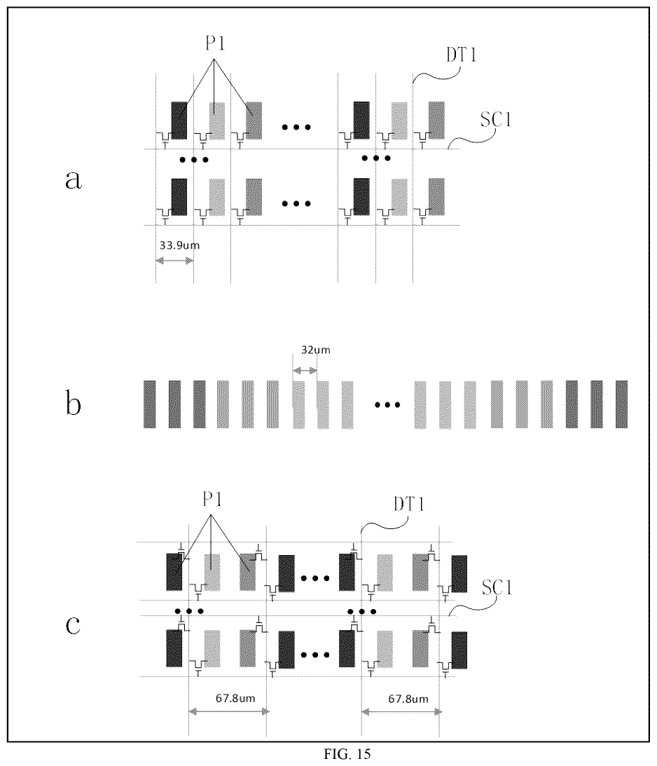

In some implementations, as shown in FIG. 14, the anti-peeping panel 12 includes a second array substrate 131, a second cell substrate 132 and a second supporting structure PS2 located between the second array substrate 131 and the second cell substrate 132, and the second supporting structure PS2 includes: a fifth support pillar PS21, located in the second light-transmitting area H2, wherein in a state without an external pressure, a fifth gap is provided between the fifth support pillar PS21 and the second array substrate 131; and a sixth support pillar PS22 and a seventh support pillar PS23 that are located in the second bridging area Q2, wherein the sixth support pillar PS22 is arranged close to the second light-transmitting area H2, and the seventh support pillar PS23 is arranged close to the anti-peeping area BB, in the state without the external pressure, a sixth gap is provided between the sixth support pillar PS22 and the second array substrate 131, and a seventh gap is provided between the seventh support pillar PS23 and the second array substrate 131. Among them, the fifth gap is greater than or equal to the sixth gap, and the sixth gap is greater than or equal to the seventh gap.

By setting the fifth support pillar PS21 in the second light-transmitting area H2, the second array substrate 131 and the second cell substrate 132 of the second light-transmitting area H2 may be supported, ensuring that the box thickness of the second light-transmitting area H2 does not change too much and improving the uniformity of the box thickness.

By setting the fifth gap, the sixth gap, and the seventh gap to gradually decrease, it may avoid frictional stress concentration caused by excessively high support pillars in the second light-transmitting area H2 and the second bridging area Q2, and avoid problems such as uneven display images and damaged image quality captured by the camera due to the frictional stress concentration.

In specific implementation, as shown in FIG. 14, the second supporting structure PS2 may include one or more (such as three in FIG. 14) sixth support pillars PS22 in the direction from the second light-transmitting area H2 pointing to the second bridging area Q2, and the plurality of sixth support pillars PS22 may be separated from each other.

In specific implementation, as shown in FIG. 14, the second supporting structure PS2 may include one or more (such as the two in FIG. 14) seventh support pillars PS23 in the direction from the second light-transmitting area H2 pointing to the second bridging area Q2, and the plurality of seventh support pillars PS23 may be separated from each other.

In some implementations, as shown in FIG. 14, the second supporting structure PS2 further includes: a second supporting wall PSW2, located between the at least one sixth support pillar PS22 and the at least one seventh support pillar PS23, and being a closed structure surrounding the second light-transmitting area H2. Furthermore, in the state without the external pressure, a gap between the second supporting wall PSW2 and the second array substrate 131 is greater than or equal to the seventh gap, and less than or equal to the sixth gap.

For example, as shown in FIG. 14, in the direction from the second light-transmitting area H2 pointing to the second bridging area Q2, the second supporting wall PSW2 is located between the plurality of (such as three shown in FIG. 14) sixth support pillars PS22 and the plurality of (such as two shown in FIG. 14) seventh support pillars PS23, and the second supporting wall PSW2 is separated from the sixth support pillars PS22 and the seventh support pillars PS23.

In some implementations, as shown in FIG. 14, the first supporting structure PS1 further includes: an eighth support pillar PS24, located in the anti-peeping area BB, wherein a size of an orthographic projection of the eighth support pillar PS24 on the light-emitting surface is less than a size of an orthographic projection of the fifth support pillar PS21 on the light-emitting surface.

In some implementations, the size of the orthographic projection of the fifth support pillar PS21 on the light-emitting surface is greater than or equal to 1 mm, and less than or equal to 10 mm.

For example, the size of the orthographic projection of the eighth support pillar PS24 on the light-emitting surface is 9 μm, and the size of the orthographic projection of the fifth support pillar PS21 on the light-emitting surface may be 1 mm, 2 mm, 3 mm, 4 mm, 5 mm, 6 mm, 7 mm, 8 mm or 9 mm, and so on.

In some implementations, as shown in FIG. 14, the anti-peeping panel 12 may further include a second liquid crystal layer 133 located between the second array substrate 131 and the second cell substrate 132.

In some implementations, as shown in FIG. 12 and FIG. 14, the display panel 11 further includes: a second light-shielding pattern 124 located in the first bridging area Q1 and arranged on a side of the first wiring close to the light-emitting surface; the anti-peeping panel 12 further includes: a third light-shielding pattern 134, located in the second bridging area Q2 and arranged on a side of the second wiring close to the light-emitting surface. Among them, an orthographic projection of the third light-shielding pattern 134 on the light-emitting surface covers an orthographic projection of the second light-shielding pattern 124 on the light-emitting surface, and a distance between a boundary of the orthographic projection of the third light-shielding pattern 134 on the light-emitting surface and a boundary of the orthographic projection of the second light-shielding pattern 124 on the light-emitting surface is greater than or equal to a preset value, the preset value is positively correlated with a thickness of an optical adhesive layer arranged between the display panel 11 and the anti-peeping panel 12.

In this implementation, the anti-peeping panel 12 may be arranged away from the light-emitting side of the display panel 11. By setting a wider third light-shielding pattern 134, the problem of oblique viewing angle light leakage caused by the thickness of the optical adhesive layer may be avoided, and the light from the backlight source may be effectively blocked.

For example, the preset value may be calculated using the following formula:
the preset value=h=tan (90°-α), where h represents the thickness of the optical adhesive layer and a represents the viewing angle. For example, when the viewing angle α is set to 80 degrees and the thickness h of the optical adhesive layer is 0.8 mm, the preset value is calculated to be 4.5 μm.

In some implementations, as shown in plan a in FIG. 15, the display panel 11 includes a plurality of first scanning signal lines SC1, a plurality of first data signal lines DT1 intersecting with the first scanning signal lines SC1, and a plurality of first sub-pixels P1 arranged in an array along a row direction and a column direction; and the first sub-pixels P1 located in a same row are connected to a same first scanning signal line SC1, and connected to different first data signal line DT1.

This implementation employs single gate technology, and in practical applications, this display panel may encounter the problem of insufficient bonding space.

For example, for a 10k display panel with a size of 42.2 inches, a resolution of 10496*1040, and a pixel per inch (PPI) of up to 250, the size of each first sub-pixel P1 in the row direction and the column direction is 33.9 μm and 101.7 μm, respectively. The driving chip is bonded to the bonding area of the display panel 11 through a chip on film. Due to the requirement of the bonding process for the arrangement period of the bonding terminals on the chip on film (COF) (such as 32 micrometers shown in plan b in FIG. 15), when a plurality of COFs need to be bonded, conflicts may occur between adjacent COFs.

To solve the aforementioned problems, in some implementations, as shown in plan b in FIG. 15, the display panel 11 includes a plurality of first scanning signal lines SC1, a plurality of first data signal lines DT1 intersecting with the first scanning signal lines SC1, and a plurality of first sub-pixels P1 arranged in an array along a row direction and a column direction; and two first sub-pixels P1 located in a same row and two adjacent columns are connected to different first scanning signal lines SC1, and connected to a same first data signal line DT1.

This implementation employs dual gate technology, which reduces the number of the first data signal lines DT1 by increasing the number of the first scanning signal lines SC1. The number of bonding terminals connecting the first data signal lines DT1 is also reduced accordingly (such as by half), further reducing the number of the driving chips and the COFs, thereby solving the problem of insufficient bonding area space.

As shown in plan b in FIG. 15, for the 10k display panel 11 with the size of 42.2 inches, the resolution of 10496*1040, and the PPI of up to 250, after employing the dual gate technology, the arrangement period of the first sub-pixel P1 in the row direction is 67.8 μm.

In some embodiments, as shown in FIG. 1, the display panel 11 further includes a gate driving circuit 14 located in the border area BZ, and the plurality of first scanning signal lines SC1 connected to different output terminals of the gate driving circuit 14. By integrating the gate driving circuit 14 into the display panel 11, that is, using Gate Driver On Array (GOA) technology, the gate driving chip may be eliminated, further reducing costs.

Due to the use of the dual gate technology, the charging time of pixels is reduced by half compared to the single gate technology. In addition, due to the time-division multiplexing of the first common electrode 112, the touch time will occupy a portion of the pixel charging time, resulting in a short pixel charging time. For the 10k display panel 11 with the size of 42.2 inches, the resolution of 10496*1040, and the PPI of up to 250, the charging time of the pixels in each row is only 6.8 μs. Moreover, when the size of the display panel 11 is large, the load on the first scanning signal line SC1 is also high. Using conventional technology, the signal attenuation (equivalent to the width of the rising edge or falling edge of the signal) on the first scanning signal line SC1 reaches more than 20 μs, far exceeding the charging time of the pixels.

In order to reduce the signal attenuation, in some implementations, as shown in FIG. 1, the same first scanning signal line SC1 may be connected to two gate driving circuits 14, and the two gate driving circuits 14 are located on two opposite sides of the effective display area AA (such as the left border and right border shown in FIG. 1). Each first scanning signal line SC1 employs bilateral driving, which may reduce the signal attenuation.

In order to reduce the signal attenuation, in some implementations, a thickness of the first scanning signal lines SC1 is greater than or equal to 6000 angstroms.

In specific implementation, thick copper technology may be used to prepare the first scanning signal line SC1, thereby reducing the resistance of the first scanning signal line SC1 and reducing the signal attenuation.

After verification, for the 10k display panel 11 with the size of 42.2 inches, the resolution of 10496*1040, and the PPI of up to 250, when the copper layer thickness of the first scanning signal line SC1 reaches 6000 angstroms or more, the signal attenuation duration on the first scanning signal line SC1 is 7.3 μs. When further employing bilateral driving, the signal attenuation duration on the first scanning signal line SC1 is 3.65 μs, which is less than the pixel charging duration of 6.8 μs, thereby improving the pixel charging efficiency.

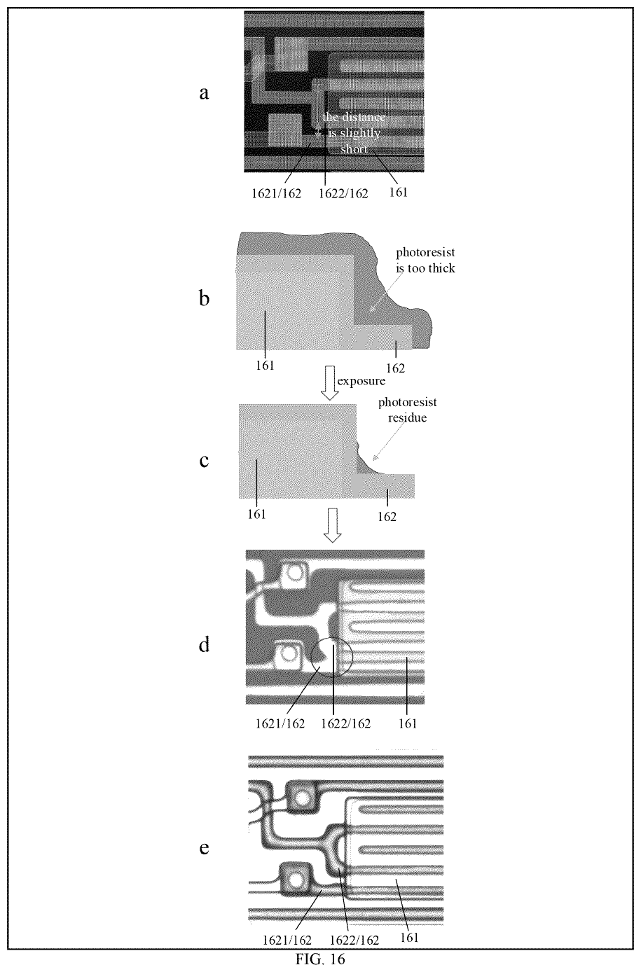

In some implementations, as shown in plan a in FIG. 16, the display panel 11 includes: a first substrate 1211 (not shown in FIG. 16), and a first conductive pattern 161 and a second conductive pattern 162 that are arranged on a side of the first substrate 1211 in stacked; the first conductive pattern 161 is arranged close to the first substrate 1211, the first conductive pattern 161 and the first scanning signal lines SC1 are arranged on a same layer and have a same material and thickness, the second conductive pattern 162 includes a plurality of second conductive wires 1621.

In specific implementation, the first scanning signal line SC1 is formed synchronously with the first conductive pattern 161. When thick copper is used for the first scanning signal line SC1 and the first conductive pattern 161, as shown in plan b to d in FIG. 16, photoresist needs to be coated to continue forming the second conductive pattern 162 on the thick copper. Due to the thick photoresist at the edge of the thick copper, photoresist residue is prone to occur after exposure, which may easily cause short circuits between adjacent second conductive wires 1621 at that position and affect the normal display of the display panel 11. When the first conductive pattern 161 and the second conductive pattern 162 are located in the border area BZ, such as in the gate driving circuit 14, the short circuit problem is particularly severe due to a smaller line spacing of the second conductive line 1621 caused by the limited space.

To solve the aforementioned problems, in some implementations, a distance between two adjacent second conductive wires 1621 is greater than or equal to 3.1 micrometers.

After verification, by changing the mask, the distance between the two adjacent second conductive wires 1621 may be increased from the conventional 2.5 micrometers to 3.1 micrometers and more, ensuring that the two adjacent second conductive wires 1621 close to the edge of the thick copper are disconnected from each other, as shown in plan e in FIG. 16.

In order to solve the above problems, in some other implementations, the coating thickness of the photoresist may also be reduced, such as changing the coating thickness of the photoresist from the conventional 2.2 μm to 1.5 μm, which may eliminate the photoresist residue. It may also increase the exposure dose, such as increasing the exposure dose from the conventional 46 mj to 93 mj, which may eliminate the photoresist residue.

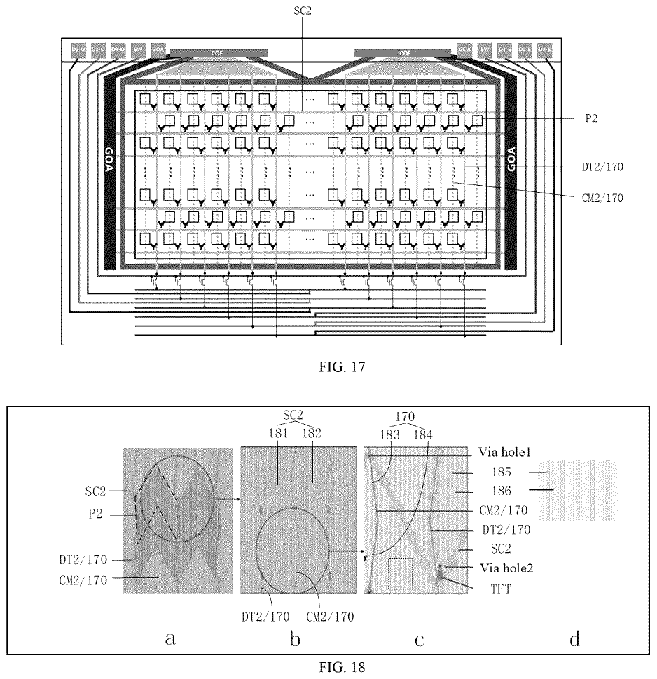

In some implementations, as shown in FIG. 15, the effective display area AA includes a plurality of first sub-pixels P1 arranged in an array along a row direction and a column direction, as shown in FIG. 17 or FIG. 18, the anti-peeping area BB includes a plurality of second sub-pixels P2 arranged in an array along the row direction and the column direction; and in the row direction and/or the column direction, a difference between a positive integer multiple of a size of the first sub-pixel P1, and a size of the second sub-pixel P2 is greater than 0 or less than 0. This may prevent the occurrence of rainbow patterns.

For example, in the column direction, the length of the second sub-pixel P2 is 4 times the length of the first sub-pixel P1 plus 0.2 μm, that is, the length of the second sub-pixel P2=101.7 μm*4+0.2 μm=407 μm. In the row direction, the width of the second sub-pixel P2 is 4 times the width of the first sub-pixel P1 plus 0.2 μm, that is, the width of the second sub-pixel P2=33.9 μm*4+0.2 μm.

In some implementations, as shown in FIG. 17, the anti-peeping area BB includes a plurality of second sub-pixels P2 arranged in an array along a row direction and a column direction, the anti-peeping panel 12 includes a plurality of second scanning signal lines SC2 and a plurality of second signal lines 170 intersecting with the second scanning signal lines SC2, the plurality of second signal lines 170 include a second common signal line CM2 and a second data signal line DT2.

In order to avoid the moiré phenomenon, as shown in FIG. 18, the second scanning signal line SC2 and the second signal line 170 are both in a zigzag structure.

In FIG. 18, there are four figures: a, b, c, and d. The latter figure is an enlarged view of the dashed box area in the previous figure.

In some implementations, as shown in FIG. 18, each of the plurality of second scanning signal lines SC2 includes a first extension line 181 and a second extension line 182 that are sequentially cross connected and alternately arranged, an angle between the first extension line 181 and the row direction and an angle between the second extension line 182 and the row direction are greater than or equal to 45°, and less than or equal to 75°, for example, the angle is 63.4° shown in FIG. 18.

In some implementations, as shown in FIG. 18, each of the plurality of second signal lines 170 includes a third extension line 183 and a fourth extension line 184 that are sequentially cross connected and alternately arranged, an angle between the third extension line 183 and the column direction and an angle between the fourth extension line 184 and the column direction are greater than or equal to 0°, and less than or equal to 15°, for example, the angle is 7° shown in FIG. 18.

In some implementations, as shown in FIG. 18, the plurality of second scanning signal lines SC2 are arranged along the column direction, two adjacent second scanning signal lines SC2 are parallel to each other; and the second common signal line CM2 and the second data signal line DT2 are alternately arranged along the row direction, two adjacent second common signal lines CM2 are parallel to each other, two adjacent second data signal lines DT2 are parallel to each other, and the second common signal line CM2 and the second data signal line DT2 that are adjacent are not parallel. This may further avoid the moiré phenomenon.

In some implementations, as shown in FIG. 17 and FIG. 18, the anti-peeping area BB includes a plurality of second sub-pixels P2 arranged in an array along a row direction and a column direction, the functional particles located in the second sub-pixel P2 include liquid crystal molecules, and the driving structure located in the second sub-pixel P2 includes: a second pixel electrode 185 and a second common electrode 186 that extend along the column direction, wherein an orthographic projection of the second pixel electrode 185 on the light-emitting surface and an orthographic projection of the second common electrode 186 on the light-emitting surface are arranged alternately and at equal intervals along the row direction.

As shown in plan d in FIG. 18, both the second pixel electrode 185 and the second common electrode 186 are strip-shaped electrodes extending along the column direction. By providing signals to the second pixel electrode 185 and the second common electrode 186 respectively, the deflection of the liquid crystal molecules in the second sub-pixel P2 may be controlled, thereby adjusting the angle of the light emitted from the anti-peeping panel 12 and achieving switching between the anti-peeping state and the shared state at any position and in any area size.

In specific implementation, the second scanning signal line SC2 may be driven by GOA, and the second data signal line DT2 may be driven by connecting to the driving chip through a chip on film. Certainly, the second scanning signal line SC2 and the second data signal line DT2 may also be driven by Chip On Array (GOA) on the array substrate, and the present application does not limit this.

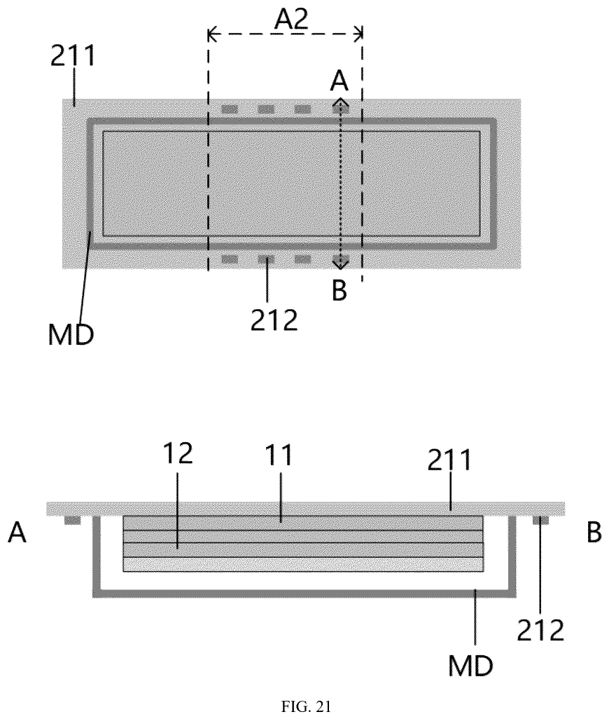

In some implementations, as shown in FIG. 21, the effective display area AA includes a second sub-display area A2, and the display module further includes: a cover plate 211, arranged close to the light-emitting surface of the display panel 11; and a vibration exciter 212, arranged on a side of the cover plate 211 close to the display panel 11, symmetrically arranged on opposite sides of the second sub-display area A2, and arranged close to an edge of the cover plate 211. In FIG. 21, the upper figure is a schematic diagram of a planar structure of the display device, and the lower figure is a schematic diagram of a sectional structure of the display device along the line AB.

By setting the vibration exciter 212, different tactile sensations of physical buttons may be achieved in the second sub-display area A2, improving interactivity. In addition, by symmetrically setting the vibration exciter 212, the vibration uniformity of the second sub-display area A2 may be improved.

Among them, the second sub-display area A2 may be used for central control display, such as the middle ⅓ area of the display module. Correspondingly, the vibration exciter 212 is attached along the two long sides of the cover plate 211 and located in the edge areas on both sides of the second sub-display area A2.

For example, as shown in FIG. 21, the size of a single vibration exciter 212 is 5.0 mm*10.0 mm*0.5 mm.

For example, as shown in FIG. 21, the display module further includes a backlight module MD, the backlight module MD is located away from the display surface of the display panel 11 and is used to provide backlight to the display panel 11.

Among them, the orthographic projection of the vibration exciter 212 on the cover plate 211 is located outside the range of the orthographic projection of the backlight module MD on the cover plate 211. The distances from the vibration exciter 212 to the edge of the cover plate 211 and the edge of the backlight module MD may be 0.5 mm or more, and the distance between the edge of the cover plate 211 and the edge of the backlight module MD may be 8 mm~15 mm.

For example, the vibration exciter 212 and the cover plate 211 may be bonded together using double-sided tape.

For example, the distance between the vibration exciters 212 is an integer multiple of the wave node, which may generate texture tactile feedback. The distance between the vibration exciters 212 may be greater than or equal to 1 mm and less than or equal to 10 mm, which depends on the required vibration mode and other factors.

In order to drive the vibration of the display panel 11, an optical adhesive with a lower elastic modulus may be used to bond the cover plate 211 and the display panel 11.

In some implementations, the display panel 11 may be a liquid crystal display panel or a self-luminous display panel, and the present application is not limited to this. Among them, the self-luminous display panel is provided with light-emitting devices therein, for example, the light-emitting devices may be organic light-emitting diodes (OLED), quantum dot light-emitting diodes (QLED), mini light-emitting diodes (Mini LED), or micro light-emitting diodes (Micro LED), etc.

The present application also provides a display device, including: the display module as provided in any implementation; and a driving component, connected to the display module, used for providing display signals and driving signals to the display module.

Persons skilled in the art may understand that the display device provided in the present application has the advantages of the above display module. The display device provided in the present application may be integrated into products such as laptops and displays, and may be used as a display in many fields such as in-vehicle displays and consumer electronics.

For example, the driving component may include at least one of the following: a microcontroller unit (MCU), and a field programmable gate array (FPGA), etc. This embodiment does not limit this.

The present application also provides a driving method, applied to the display module as provided in any implementation, and the driving method including:
step S01: providing a display signal to the display panel 11, to display an image on the display panel 11;
step S02: providing a driving signal to the driving structure, wherein the driving structure responds to the driving signal to form the electric field, the electric field is used for controlling the functional particles to move, so that the target sub-display area switches to the anti-peeping state or the shared state, wherein the target sub-display area includes one or more sub-display areas.

The executing subject of the driving method provided in the present application may be, for example, a driving component in a display device.

In some implementations, as shown in FIG. 2, the display panel 11 includes a plurality of sub-display areas, and the step S01 may specifically include:
step S11: providing different display signals to different sub-display areas, to display different display images on different sub-display areas.

In some implementations, as shown in FIG. 2, the plurality of sub-display areas include a second sub-display area A2 and a third sub-display area A3 that are adjacent, the anti-peeping area BB includes a first anti-peeping area and a second anti-peeping area, in a normal direction of the light-emitting surface, the first anti-peeping area overlaps with the second sub-display area A2, the second anti-peeping area overlaps with the third sub-display area A3, and the step S02 may specifically include:
step S21: providing a first driving signal to the driving structure in the first anti-peeping area, to make the second sub-display area A2 in the shared state; and
step S22: providing a second driving signal to the driving structure in the second anti-peeping area, to make the third sub-display area A3 in the anti-peeping state.

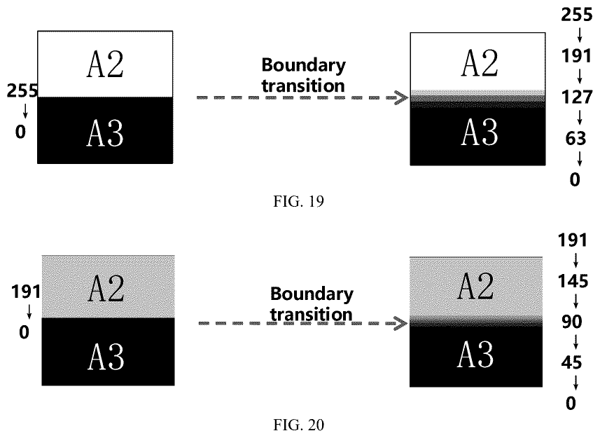

As shown in the left figure in FIG. 19 or FIG. 20, for the second sub-display area A2 and the third sub-display area A3 that are adjacent, when the second sub-display area A2 is in the shared state and the third sub-display area A3 is in the anti-peeping state, a more obvious “boundary feeling” may form at the boundary between the second sub-display area A2 and the third sub-display area A3.

In order to reduce the “boundary feeling”, in some implementations, as shown in the right figures in FIG. 19 and FIG. 20, a first pixel, a second pixel and a third pixel are arranged at a junction of the second sub-display area A2 and the third sub-display area A3, in a direction from the second sub-display area A2 pointing to the third sub-display area A3, the first pixel, the second pixel and the third pixel are sequentially arranged, and the step S11 may specifically include:
step S31: providing a first display signal to the first pixel, to make the first pixel display a first grayscale;
step S32: providing a second display signal to the second pixel, to make the second pixel display a second grayscale; and
step S33: providing a third display signal to the third pixel, to make the third pixel display a third grayscale.

Among them, the second grayscale is between the first grayscale and the third grayscale. For example, the second grayscale may be close to the median value between the first grayscale and the third grayscale.

In this implementation, at the junction between the second sub-display area A2 and the third sub-display area A3, grayscale transitions are formed by segmenting the grayscale to make the boundary smoother, thereby eliminating the “boundary feeling” in the anti-peeping/shared area.

For example, as shown in FIG. 19, the display grayscale of the second sub-display area A2 is 255, and the display grayscale of the third sub-display area A3 is 0. Segmentation is performed on the grayscale 255 to the grayscale 0, the first grayscale is 255, the third grayscale is 0, and the second grayscale may be 127. Segmentation is further performed on the grayscale 255 to the grayscale 127, the first grayscale is 255, the third grayscale is 127, and the second grayscale may be 191. Segmentation is further performed on the grayscale 127 to the grayscale 0, the first grayscale is 127, the third grayscale is 0, and the second grayscale may be 63. In this way, from the second sub-display area A2 to the third sub-display area A3, the grayscales of the pixels at the junction are displayed in a transitional manner in the order of 255, 191, 127, 63, and 0.

For example, as shown in FIG. 20, the display grayscale of the second sub-display area A2 is 191, and the display grayscale of the third sub-display area A3 is 0. Segmentation is performed on the grayscale 191 to the grayscale 0, the first grayscale is 191, the third grayscale is 0, and the second grayscale may be 90. Segmentation is further performed on the grayscale 191 to the grayscale 90, the first grayscale is 191, the third grayscale is 90, and the second grayscale may be 145. Segmentation is further performed on the grayscale 90 to the grayscale 0, the first grayscale is 90, the third grayscale is 0, and the second grayscale may be 45. In this way, from the second sub-display area A2 to the third sub-display area A3, the grayscales of the pixels at the junction are displayed in a transitional manner in the order of 191, 145, 90, 45, and 0.

In FIG. 19 and FIG. 20, each grayscale occupies 1 pixel in the direction from the second sub-display area A2 to the third sub-display area A3.

In specific implementation, the number of the segmented grayscales and the number of pixels displaying each grayscale from the second sub-display area A2 to the third sub-display area A3 may be set according to actual needs.

It should be noted that the driving method may also include more steps, which may be determined according to the actual needs, and the present application does not limit this. For a detailed explanation of the driving method and its technical effects, please refer to the description of the implementations of the display module in the previous text, which will not be repeated here.

In the present application, the meaning of “plurality of” refers to two or more, and the meaning of “at least one” refers to one or more, unless otherwise specified.

In the present application, the terms “up”, “down”, etc. indicate orientation or positional relationships based on the orientation or positional relationships shown in the accompanying drawings, only for the convenience of describing the present application and simplifying the description, and do not indicate or imply that the device or component referred to must have a specific orientation, be constructed and operated in a specific orientation, and therefore cannot be understood as a limitation of the present application.

In the specification, the terms “including/comprising”, “containing”, or any other variation thereof are intended to encompass non-exclusive inclusion, such that a process, method, product, or equipment that includes a series of elements includes not only those elements, but also other elements not explicitly listed, or elements inherent to such process, method, product, or equipment. Without further limitations, the element defined by the statement “including one . . . ” does not exclude the existence of other identical elements in the process, method, product, or device that includes the element in question.

The terms “one embodiment”, “some embodiments”, “exemplary embodiments”, “one or more embodiments”, “examples”, “one example”, “some examples”, etc. referred to in the specification are intended to indicate that specific features, structures, materials, or characteristics related to the embodiment or example are included in at least one embodiment or example disclosed herein. The schematic representation of the above terms does not necessarily refer to the same embodiment or example. In addition, the specific features, structures, materials, or characteristics described may be included in any appropriate manner in any one or more embodiments or examples.

In the specification, relational terms such as first and second are only used to distinguish one entity or operation from another, and do not necessarily require or imply any actual relationship or order between these entities or operations.

When describing some embodiments, expressions such as “coupling” and “connection” may be used. For example, in describing some embodiments, the term “connection” may be used to indicate that two or more components have direct physical or electrical contact with each other. For example, in describing some embodiments, the term “coupling” may be used to indicate that two or more components have direct physical or electrical contact. However, the term “coupled” or “communicably coupled” may also refer to two or more components that do not have direct contact with each other but still cooperate or interact with each other. The embodiments disclosed here are not necessarily limited to the content of the specification.

“At least one of A, B, and C” has the same meaning as “at least one of A, B, or C” and includes the following combinations of A, B, and C: only A, only B, only C, a combination of A and B, a combination of A and C, a combination of B and C, and a combination of A, B, and C.

“A and/or B” includes the following three combinations: only A, only B, and a combination of A and B.

As used in the specification, the term “if” is optionally interpreted as meaning “when” or “at” or “in response to a determination” or “in response to a detection” depending on the context. Similarly, depending on the context, the phrases “if determined . . . ” or “if [stated condition or event] is detected” may be interpreted as referring to “when determined . . . ” or “in response to determining . . . ” or “when [stated condition or event] is detected” or “in response to detecting [stated condition or event]”.

The use of “used for” or “configured as” in the specification implies an open and inclusive language, which does not exclude devices that are applicable or configured to perform additional tasks or steps.

The use of “based on” or “according to” in the specification implies openness and inclusiveness. A process, step, calculation, or other action based on one or more of the conditions or values described, which may be based on other conditions or beyond the values described in practice. The process, steps, calculations, or other actions based on one or more of the stated conditions or values may, in practice, be based on other conditions or beyond the stated values.

As used in the specification, “about”, “roughly”, or “approximately” include the values described and the average value within an acceptable deviation range of a specific value, where the acceptable deviation range is determined by persons skilled in the art taking into account the measurement being discussed and the errors associated with the measurement of a specific quantity (i.e., limitations of the measurement system).

As used in the specification, “parallel”, “vertical”, “equal”, and “flush” include the situations described and situations that are similar to the described situations, and the range of the similar situations is within an acceptable deviation range, where the acceptable deviation range is determined by persons skilled in the art considering the measurement being discussed and the errors associated with the measurement of a specific quantity (i.e., the limitations of the measurement system). For example, “parallel” includes absolute parallelism and approximate parallelism, where the acceptable deviation range for approximate parallelism may be within 5° of deviation; “vertical” includes absolute vertical and approximate vertical, where the acceptable deviation range for approximate vertical may also be within 5° of deviation, for example. “Equal” includes absolute equality and approximate equality, where the acceptable deviation range for approximate equality may be, for example, that the difference between the equal two is less than or equal to 5% of either one. “Flush” includes absolute flush and approximate flush, where the acceptable deviation range for approximate flush may be, for example, that the distance between the flush two is less than or equal to 5% of either dimension.

It should be understood that when a layer or component is referred to as being on another layer or substrate, it may be directly on another layer or substrate, or there may be an intermediate layer between the layer or component and another layer or substrate.

The specification describes exemplary implementations with reference to sectional diagram and/or plane diagram as idealized illustrative figures. In the attached figures, the thickness of the layers and areas has been enlarged for clarity. Therefore, it may be assumed that there may be changes in the shape relative to the drawings due to factors such as manufacturing technology and/or tolerances. Therefore, the exemplary implementations should not be interpreted as limited to the shapes of the areas shown in the specification, but rather include shape deviations caused by, for example, manufacturing. For example, etched areas shown as rectangles typically have curved features. Therefore, the areas shown in the figures are essentially illustrative, and their shapes are not intended to show the actual shape of the area of the device, nor are they intended to limit the scope of the exemplary implementations.

Finally, it should be noted that the above embodiments are only used to illustrate the technical solution of the present application and not to limit it. Although the present application has been described in detail with reference to the aforementioned embodiments, those skilled in the art should understand that they may still modify the technical solutions described in the aforementioned embodiments, or equivalently replace some of the technical features. And these modifications or substitutions do not depart from the essence and scope of the corresponding technical solutions disclosed in the present application.

1. A display module, comprising:
a display panel, comprising an effective display area, wherein the effective display area comprises at least one sub-display area; and
an anti-peeping panel, arranged on at least one side of the display panel in stacked, and arranged close to a light-emitting surface of the display panel and/or arranged away from the light-emitting surface, wherein the anti-peeping panel comprises an anti-peeping area, the anti-peeping area comprises a driving structure and functional particles, the driving structure is used for forming an electric field, and the electric field is used for driving the functional particles to move, so that a target sub-display area is in an anti-peeping state or a shared state, wherein the target sub-display area comprises one or more sub-display areas.

2. The display module according to claim 1, wherein the display panel further comprises:
a border area, located on at least one side of the effective display area;
an ambient light sensing device, located in the border area, wherein the ambient light sensing device comprises a first thin-film transistor and a second thin-film transistor, the first thin-film transistor comprises a first active layer, and the second thin-film transistor comprises a second active layer; and
a light-shielding layer, located on a side of the ambient light sensing device close to the light-emitting surface, wherein the light-shielding layer is provided with a first opening and a first light-shielding pattern, in a normal direction of the light-emitting surface, the first opening penetrates the light-shielding layer, an orthographic projection of the first opening on the light-emitting surface at least partially overlaps with an orthographic projection of the first active layer on the light-emitting surface, and an orthographic projection of the first light-shielding pattern on the light-emitting surface at least covers an orthographic projection of the second active layer on the light-emitting surface.

3. The display module according to claim 2, wherein the display panel further comprises:
a third thin-film transistor, located in the effective display area, wherein the third thin-film transistor comprises a third active layer, a size of the orthographic projection of the first active layer on the light-emitting surface is less than a size of an orthographic projection of the third active layer on the light-emitting surface.

4. The display module according to claim 2, wherein the ambient light sensing device comprises a plurality of first thin-film transistors and a plurality of second thin-film transistors;
gates of the plurality of first thin-film transistors are connected to a first gate lead, drains of the plurality of first thin-film transistors are connected to a first drain lead, and sources of the plurality of first thin-film transistors are connected to a first source lead; and
gates of the plurality of second thin-film transistors are connected to a second gate lead, drains of the plurality of second thin-film transistors are connected to a second drain lead, and sources of the plurality of second thin-film transistors are connected to a second source lead.

5. The display module according to claim 4, wherein the first gate lead is located on a side of the first active layer away from the light-emitting surface, and an orthographic projection of the first gate lead on the light-emitting surface at least covers orthographic projections of a plurality of first active layers on the light-emitting surface; and
the second gate lead is located on a side of the second active layer away from the light-emitting surface, and an orthographic projection of the second gate lead on the light-emitting surface at least covers orthographic projections of a plurality of second active layers on the light-emitting surface.

6. The display module according to claim 5, wherein a distance between a boundary of the orthographic projection of the first gate lead on the light-emitting surface and a boundary of the orthographic projection of the first active layer on the light-emitting surface is greater than or equal to 3 micrometers; and
a distance between a boundary of the orthographic projection of the second gate lead on the light-emitting surface and a boundary of the orthographic projection of the second active layer on the light-emitting surface is greater than or equal to 3 micrometers.

7. The display module according to claim 1, wherein the effective display area comprises a first sub-display area, the display panel further comprises a first light-transmitting area and a first bridging area located on at least one side of the first light-transmitting area, and the first sub-display area is located on at least one side of the first bridging area;
the anti-peeping panel further comprises a second light-transmitting area and a second bridging area located on at least one side of the second light-transmitting area, and the anti-peeping area is located on at least one side of the second bridging area;
wherein, in the normal direction of the light-emitting surface, the first light-transmitting area at least partially overlaps with the second light-transmitting area, and the first light-transmitting area and the second light-transmitting area are capable of transmitting ambient light.

8. The display module according to claim 7, wherein the effective display area comprises:
a plurality of first sub-pixels, comprising a first domain sub-pixel and a first adjacent sub-pixel, wherein the first adjacent sub-pixel is arranged close to the first bridging area, the first domain sub-pixel is located on a side of the first adjacent sub-pixel away from the first bridging area, and an opening area of the first adjacent sub-pixel is less than or equal to an opening area of the first domain sub-pixel.

9. The display module according to claim 7, wherein the display panel further comprises:
a touch control circuit, wherein the touch control circuit comprises a plurality of touch partitions, touch electrodes located in a same touch partition are connected to a same bonding terminal, and touch electrodes located in different touch partitions are connected to different bonding terminals;
wherein the plurality of touch partitions comprise a first touch partition and a second touch partition, the first touch partition is arranged close to the first bridging area, the second touch partition is located on a side of the first touch partition away from the first bridging area, and an area of the first touch partition is greater than or equal to an area of the second touch partition.

10. (canceled)

11. The display module according to claim 9, wherein the effective display area comprises a plurality of first sub-pixels, and each of the plurality of first sub-pixels comprises:
a first pixel electrode and a first common electrode, wherein orthographic projections of the first pixel electrode and the first common electrode on the light-emitting surface are arranged alternately along a first direction;
wherein a plurality of first common electrodes located in a same touch partition are connected to each other and reused as the touch electrodes, and first common electrodes located in different touch partitions are insulated from each other.

12. The display module according to claim 7, wherein the display panel comprises a first array substrate, a first cell substrate, and a first supporting structure located between the first array substrate and the first cell substrate, the first supporting structure comprises:
a first support pillar, located in the first light-transmitting area, wherein in a state without an external pressure, a first gap is provided between the first support pillar and the first array substrate.

13. The display module according to claim 12, wherein the first supporting structure further comprises:
at least one second support pillar and at least one third support pillar that are located in the first bridging area, wherein the at least one second support pillar is arranged close to the first light-transmitting area, and the at least one third support pillar is arranged close to the first sub-display area, in the state without the external pressure, a second gap is provided between the second support pillar and the first array substrate, and a third gap is provided between the third support pillar and the first array substrate;
wherein the first gap is greater than or equal to the second gap, and the second gap is greater than or equal to the third gap.

14. The display module according to claim 13, wherein the first supporting structure further comprises:
a first supporting wall, located between the at least one second support pillar and the at least one third support pillar, and being a closed structure surrounding the first light-transmitting area; wherein
in the state without the external pressure, a fourth gap is provided between the first supporting wall and the first array substrate, the fourth gap is greater than or equal to the third gap, and less than or equal to the second gap.

15. The display module according to claim 12, wherein the first supporting structure further comprises:
a fourth support pillar, located in the first sub-display area, wherein a size of an orthographic projection of the fourth support pillar on the light-emitting surface is less than a size of an orthographic projection of the first support pillar on the light-emitting surface.

16. The display module according to claim 12, wherein a size of an orthographic projection of the first support pillar on the light-emitting surface is greater than or equal to 1 mm, and less than or equal to 10 mm.

17. The display module according to claim 7, wherein the anti-peeping panel comprises a second array substrate, a second cell substrate and a second supporting structure located between the second array substrate and the second cell substrate, and the second supporting structure comprises:
a fifth support pillar, located in the second light-transmitting area, wherein in a state without an external pressure, a fifth gap is provided between the fifth support pillar and the second array substrate; and
a sixth support pillar and a seventh support pillar that are located in the second bridging area, wherein the sixth support pillar is arranged close to the second light-transmitting area, and the seventh support pillar is arranged close to the anti-peeping area, in the state without the external pressure, a sixth gap is provided between the sixth support pillar and the second array substrate, and a seventh gap is provided between the seventh support pillar and the second array substrate;
wherein the fifth gap is greater than or equal to the sixth gap, and the sixth gap is greater than or equal to the seventh gap.

18. The display module according to claim 7, wherein a first wiring is arranged in the first bridging area, the first wiring is used for connecting wirings in the first sub-display area separated by the first light-transmitting area, a second wiring is arranged in the second bridging area, and the second wiring is used for connecting wirings in the anti-peeping area separated by the second light-transmitting area;
the display panel further comprises: a second light-shielding pattern, located in the first bridging area and arranged on a side of the first wiring close to the light-emitting surface;
the anti-peeping panel further comprises: a third light-shielding pattern, located in the second bridging area and arranged on a side of the second wiring close to the light-emitting surface;
wherein an orthographic projection of the third light-shielding pattern on the light-emitting surface covers an orthographic projection of the second light-shielding pattern on the light-emitting surface, and a distance between a boundary of the orthographic projection of the third light-shielding pattern on the light-emitting surface and a boundary of the orthographic projection of the second light-shielding pattern on the light-emitting surface is greater than or equal to a preset value, the preset value is positively correlated with a thickness of an optical adhesive layer arranged between the display panel and the anti-peeping panel.

19. The display module according to claim 1, wherein the display panel comprises a plurality of first scanning signal lines, a plurality of first data signal lines intersecting with the first scanning signal lines, and a plurality of first sub-pixels arranged in an array along a row direction and a column direction; and
two first sub-pixels located in a same row and two adjacent columns are connected to different first scanning signal lines, and connected to a same first data signal line, a thickness of the first scanning signal lines is greater than or equal to 6000 angstroms.

20. (canceled)

21. (canceled)

22. (canceled)

23. (canceled)

24. (canceled)

25. (canceled)

26. A display device, comprising:
the display module according to claim 1; and
a driving component, connected to the display module, and used for providing a display signal and a driving signal to the display module.

27. A driving method, applied to the display module according to claim 1, and the driving method comprises:
providing a display signal to the display panel, to display an image on the display panel;
providing a driving signal to the driving structure, wherein the driving structure responds to the driving signal to form the electric field, the electric field is used for controlling the functional particles to move, so that the target sub-display area switches to the anti-peeping state or the shared state, wherein the target sub-display area comprises one or more sub-display areas.

28. (canceled)

29. (canceled)

30. (canceled)
